(19) United States
(12) Patent Application Publication
(10) Pub. No.: US 2015/0207104 A1
(43) Pub. Date: Jul. 23, 2015

(54) LAMINATE, METHOD FOR PRODUCING LAMINATE, ELECTRODE, EL ELEMENT, SURFACE LIGHT EMITTER, AND SOLAR CELL

(71) Applicant: MITSUBISHI RAYON CO., LTD., TOKYO (JP)

(72) Inventors: Kazunori Mukunoki, Kanagawa (JP); Yumiko Saeki, Kanagawa (JP); Toshiaki Hattori, Kanagawa (JP); Yukichi Konami, Aichi (JP); Kouji Furukawa, Jiangsu Province (CN)

(21) Appl. No.: 14/415,141

(22) PCT Filed: Jul. 22, 2013
(86) PCT No.: PCT/JP2013/069768

§ 371 Date: Jan. 16, 2015

(30) Foreign Application Priority Data
Jul. 25, 2012 (JP) 2012-164352

(51) Int. Cl. H01L 51/52; H01L 33/38; H01L 33/58; H01L 31/0224

(52) U.S. Cl. CPC H01L 51/5268; H01L 31/022425; H01L 33/38; H01L 33/58; H01L 51/5209; H01L 51/5225

(57) ABSTRACT

A laminate is described, including a substrate, an undercoat layer on the substrate, and an inorganic film on the undercoat layer. The material of the inorganic film is at least one material of a conductive metal oxide and a metal nitride. In an image obtained by Fourier transforming an image obtained by using an atomic force microscope to take a picture of a surface of the inorganic film, the azimuth angle of the image obtained from the Fourier transformation from the center of the image toward the direction of 12 o'clock is set to 0°. In approximate curves of 36 brightness value plots obtained by radially plotting the brightness values every 10° from 0°, a maximum value is observed in 18 or more of the approximate curves.

### BACKGROUND OF THE INVENTION

1. Field of the Invention

The invention relates to a laminate, a method for producing a laminate, an electrode, an EL element, a surface light emitter, and a solar cell.

This application claims priority benefits of Japanese Patent Application no. 2012-164352, filed on Jul. 25, 2012, of which the entirety is incorporated herein.

2. Description of Related Art

The organic electroluminescence (EL) element and the inorganic EL element are known surface light emitters. A known organic EL element includes a transparent substrate, a transparent electrode disposed on the surface of the transparent substrate, a back electrode containing a metal thin film disposed separately from the transparent electrode, and a light-emitting layer disposed between the transparent electrode and the back electrode and containing a light-emitting material of an organic compound.

In the organic EL element, the light-emitting layer emits light via the combination of holes from the transparent electrode and electrons from the back electrode in the light-emitting layer. Light emitted from the light-emitting layer penetrates the transparent electrode and the transparent substrate and exits from the exit surface (surface of transparent substrate). Moreover, a portion of light emitted from the light-emitting layer is reflected by the metal thin film of the back electrode, and then penetrates the light-emitting layer, the transparent electrode, and the transparent substrate and exits from the exit surface.

In the organic EL element, an interface of the light-emitting layer and the transparent electrode, an interface of the transparent electrode and the transparent substrate, and an interface of the transparent substrate and outside air are included. The critical angle in each of the interfaces depends on the refraction indexes of the respective materials forming the interface. Light entering the interface at an angle greater than the critical angle is totally reflected at the interface. For instance, if light enters the light-emitting layer at an angle greater than the critical angle at the interface of the light-emitting layer and the transparent electrode, the light is totally reflected and confined inside the light-emitting layer. Similarly, if light enters the interface of the transparent electrode and the transparent substrate or the interface (exit surface) of the transparent substrate and outside air, etc. at an angle greater than the critical angle, the light is totally reflected at the interface and confined inside the surface light emitter. Thus, a part of light cannot exit to the outside, causing the problem of low light extraction efficiency.

To solve the problem, Patent Literature 1 provides a method in which a substrate and an organic EL layer are folded. Moreover, Patent Literature 2 provides a method in which an uneven structure is transferred by using a mold having an uneven structure.

### PRIOR-ART LITERATURES

### Patent Literatures

[Patent Literature 1] Japanese Patent Publication No. 2009-021089

[Patent Literature 2] International Publication No. 2012/043828 pamphlet.

### SUMMARY OF THE INVENTION

### Problem to Be Solved by the Invention

However, in the method provided in Patent Literature 1, since an uneven structure is formed on the whole organic EL element, the luminous stability is unsatisfactory. Moreover, since in the above method, the substrate is limited to a retractable stretched film and heat or stress is applied to the entire organic EL element, gas barrier properties or dimensional stability is poor, and therefore the method is not suitable for an application for which long service life is required, such as a display apparatus or lighting. Moreover, in the method provided in Patent Literature 2, a step in which an uneven structure is formed by mold transfer is included, and productivity is insufficient.

An object of the invention is to provide a laminate used to obtain a surface light emitter having superior light extraction efficiency or a solar cell having superior light confining efficiency.

Moreover, an object of the invention is to provide a method in which a laminate having an inorganic film on the surface of an uneven structure can be effectively obtained.

### Means for Solving the Problem

1) An aspect of the invention relates to a laminate including a substrate, an undercoat layer on the substrate, and an inorganic film on the undercoat layer, wherein the inorganic film includes at least one material of a conductive metal oxide and a conductive metal nitride. In an image obtained by Fourier transforming an image obtained by using an atomic force microscope to take a picture of the surface of the inorganic film, the azimuth angle of the image obtained from the Fourier transformation from the center of the image toward the direction of 12 o'clock. In first approximate curves of 36 brightness value plots obtained by radially plotting the brightness values every 10° from 0°, a maximum value is observed in 18 or more of the first approximate curves.

2) In the laminate of item 1), in a second approximate curve of the plot obtained by summing the 36 brightness value plots, the frequency at which the brightness value is a minimum between the frequency of 0.2 μm⁻¹ and a frequency at which the brightness value is a maximum value is set as frequency A, the largest frequency among the frequencies at which the brightness values are half of the maximum value is set as frequency B, and the difference of the reciprocal of frequency A and the reciprocal of frequency B may be 0.01 to 10 μm.

3) In the laminate of items 1) and 2), the average pitch of the uneven structure of the surface of the inorganic film may be 0.05 to 4 μm.

4) In the laminate of items 1) to 3), the average height of the protruding portions of the uneven structure of the surface of the inorganic film may be 0.01 to 2 _{μm.}

5) In the laminate of items 1) to 4), the surface roughness Ra, the line roughness Ra′, the maximum value Ra′(max) of line roughness, and the minimum value Ra′(min) of line roughness of the surface of the inorganic film may satisfy formula (1) for a laminate of claim 1:

0.13≦(Ra′(max)−Ra′(min))Ra0.82 (1).

6) In the laminate of items 1) to 5), the elastic modulus of the undercoat layer may be 1800 MPa or less.

7) In the laminate of items 1) to 6), the inorganic film may comprise at least one material selected from the group consisting of indium tin oxide, indium zinc oxide, indium oxide, zinc oxide, tin oxide, zirconium oxide, indium nitride, gallium nitride, aluminum nitride, zirconium nitride, and titanium nitride.

8) Moreover, another aspect of the invention relates to a method for producing a laminate, which includes the following steps. An active energy ray curable composition is coated on a substrate, containing a monomer having at least one group of a urethane group, a phenyl group, and an alkylene oxide group. The active energy ray curable composition is irradiated with an active energy ray to be cured and form an undercoat layer. An inorganic film comprising at least one of a conductive metal oxide and a conductive metal nitride is laminated on the undercoat layer via any one of a sputtering method, an evaporation method, and a chemical vapor deposition (CVD) method to form an uneven structure on the surface.

9) In the method for producing a laminate of item 8), the inorganic film may comprise at least one material selected from the group consisting of indium tin oxide, indium zinc oxide, indium oxide, zinc oxide, tin oxide, zirconium oxide, indium nitride, gallium nitride, aluminum nitride, zirconium nitride, and titanium nitride.

10) In the method for a laminate of items 8) and 9), the method for the lamination on the undercoat layer may be a sputtering method or an evaporation method.

11) Another aspect of the invention relates to an electrode including the laminate of one of items 1) to 7). The electrode includes: a substrate, an undercoat layer on the substrate, and a conductive inorganic film disposed on the undercoat layer and having an uneven structure at the surface thereof.

12) Another aspect of the invention relates to an EL element including the laminate of one of items 1) to 7).

13) Another aspect of the invention relates to a surface light emitter including the EL element. The surface light emitter includes: a substrate, an undercoat layer on the substrate, a first electrode disposed on the undercoat layer and having an uneven structure at the surface thereof, a second electrode separately disposed from the first electrode, and a light-emitting layer disposed between the first electrode and the second electrode.

14) Another aspect of the invention relates to a solar cell including the laminate of one of items 1) to 7). The solar cell includes: a substrate, an undercoat layer on the substrate, a transparent electrode disposed on the undercoat layer and having an uneven structure at the surface thereof, a photoelectric conversion layer, and a back electrode.

### Effects of the Invention

Via the laminate in an aspect of the invention, a surface light emitter having superior light extraction efficiency or a solar cell having superior light confining efficiency can be obtained.

Moreover, via the method for producing a laminate in another aspect of the invention, a laminate having an inorganic film on the surface of the uneven structure can be effectively obtained, and a surface light emitter having superior light extraction efficiency or a solar cell having superior light confining efficiency can be obtained from the obtained laminate.

Moreover, via the electrode in still another aspect of the invention, a surface light emitter having superior light extraction efficiency or a solar cell having superior light confining efficiency can be obtained.

Moreover, via the EL element in still another aspect of the invention, a surface light emitter having superior light extraction efficiency can be obtained.

Moreover, the light extraction efficiency of the surface light emitter in still another aspect of the invention is superior.

Moreover, the light confining efficiency of the solar cell in still another aspect of the invention is superior.

### BRIEF DESCRIPTION OF THE DRAWINGS

FIG. 1 is a cross-sectional view of an example of a laminate of the invention.

FIG. 2 is a cross-sectional view of an example of a surface light emitter of the invention.

FIG. 3 is a cross-sectional view of an example of a surface light emitter of the invention.

FIG. 4 is a cross-sectional view of an example of a solar cell of the invention.

FIG. 5 is a cross-sectional view of an example of a solar cell of the invention.

FIG. 6 shows the result (50 μm×50 μm) of surface shape measurement of the laminate obtained in Example 5.

FIG. 7 shows the result (50 μm×50 μm) of surface shape measurement of the laminate obtained in Example 10.

FIG. 8 shows the result (50 μm×50 μm) of surface shape measurement of the laminate obtained in Example 12.

FIG. 9 shows the result (50 μm×50 μm) of surface shape measurement of the laminate obtained in Example 15.

FIG. 10 shows an example of the result (50 μm×50 μm) of surface shape measurement of a laminate of the invention.

FIG. 11 shows an example of an image obtained by Fourier transforming the result of surface shape measurement of a laminate of the invention.

FIG. 12 is a plot of brightness values obtained from the image obtained from the Fourier transformation and shown in FIG. 11.

FIG. 13 is obtained by correcting the plot shown in FIG. 12 with the moving average calculated from the plot shown in FIG. 12.

FIG. 14 is a first sixth-order polynomial approximate curve made from the plot shown in FIG. 13.

FIG. 15 shows an example of a second sixth-order polynomial approximate curve.

FIG. 16 shows the result (50 μm×50 μm) of surface shape measurement of the laminate obtained in Example 21.

FIG. 17 shows the result (50 μm×50 μm) of surface shape measurement of the laminate obtained in Comparative Example 9.

### DESCRIPTION OF THE EMBODIMENTS

In the followings, embodiments of the invention are described with figures, but the aspects of the invention are not limited to the figures.

In this specification, the active energy ray refers to, for instance, visible light, ultraviolet (UV), electron beam, plasma, or heat ray (such as infrared).

Moreover, in this specification, (poly)alkylene glycol refers to polyalkylene glycol or alkylene glycol.

Furthermore, in this specification, (meth)acrylate refers to acrylate or methacrylate.

(Laminate 10)

A laminate 10 in this embodiment includes a substrate 11, an undercoat layer 12, and an inorganic film 13 that are laminated in order.

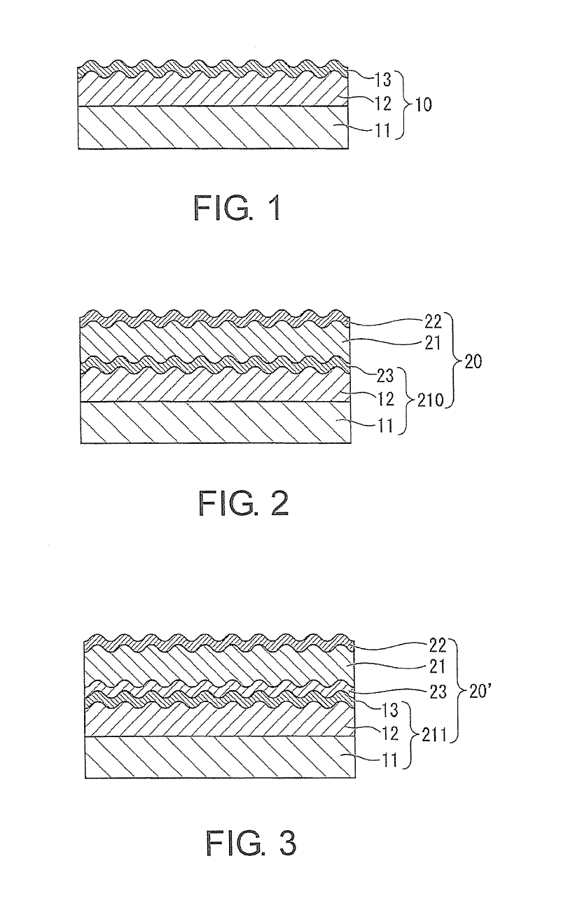

The laminate 10 of the invention may be, for instance, the laminate 10 shown in FIG. 1.

(Substrate 11)

Shapes of the substrate 11 include a film, a sheet, a board, and a foil, etc. The thickness of the substrate 11 may be suitably selected according to application, and is preferably 25 to 5000 μm, more preferably 50 to 2500 μm, and still more preferably 100 to 1000 μm.

The material of the substrate 11 may be, for example, an inorganic material such as glass or ceramic, a metal such as SUS (stainless steel), copper or aluminum, or a resin such as a polyester resin (such as polyethylene terephthalate, polybutylene terephthalate, or polyethylene naphthalate), an acrylic resin (such as polymethyl methacrylate), a carbonate-based resin, a vinyl chloride resin, a styrene resin (such as polystyrene or ABS resin), a cellulose resin (such as diacetyl cellulose or triacetyl cellulose), an olefin-based resin, an imide-based resin or an aramid resin. Among the materials of the substrate 11, in terms of superior dimensional stability or heat resistance, glass, a metal material, a polyester-based resin, and an imide-based resin are preferred, and glass and metal are more preferred. Moreover, in the case that a resin is used as the material of the substrate 11, in terms of superior gas barrier properties, an inorganic compound such as silicon oxide or silicon nitride is preferably made into a film on the surface of the substrate 11.

In a case that the laminate 10 of this embodiment is used as a surface light emitter or a solar cell, in terms of superior dimensional stability, the material of the substrate 11 is preferably glass, a polyester-based resin, or an imide-based resin, and more preferably glass.

(Undercoat Layer 12)

In terms of readily generating a buckling phenomenon forming an uneven structure, the material of the undercoat layer 12 is preferably a material having an elastic modulus of 10 to 1800 MPa, more preferably a material having an elastic modulus of 15 to 1600 MPa, and still more preferably a material having an elastic modulus of 20 to 1500 MPa.

Moreover, the elastic modulus is obtained by measuring five locations under the conditions of a force of 50 mN/10 sec and a creep time of 5 sec for the average value by using a microhardness tester.

To readily perform lamination, the lamination method of the undercoat layer 12 on the substrate 11 preferably includes coating an active energy ray curable composition for forming the undercoat layer, and then curing the active energy ray curable composition by irradiating the same with an active energy ray.

The coating method of the active energy ray curable composition on the substrate 11 may include a known coating method such as brush coating, spray coating, dip coating, spin coating, or flow coating. Among the coating methods, in terms of superior coating workability, and smoothness and uniformity of the active energy ray curable composition, spray coating and spin coating are preferred.

In the case that a high-pressure mercury lamp is used as the active energy ray source, the integrated dose of UV light can be suitably selected according to the active energy ray curable composition used, and is preferably 200 to 6000 mJ/cm², more preferably 300 to 5000 mJ/cm².

In terms of superior adhesion with the inorganic film 13 and satisfying the elastic modulus of the material used as the undercoat layer 12 such that a buckling phenomenon forming an uneven structure is readily generated, the active energy ray curable composition is preferably a composition containing a monomer (A) having at least one of a urethane group, a phenyl group, and an alkylene oxide group, a monomer (B) other than the monomer (A), and a photopolymerization initiator (C).

(Monomer (A))

The monomer (A) has at least one of a urethane group, a phenyl group, and an alkylene oxide group.

Examples of the monomer (A) include: a compound obtained by reacting a diisocyanate compound (such as tolylene diisocyanate, isophorone diisocyanate, xylene diisocyanate, or dicyclohexyl methane diisocyanate) with a (meth)acrylate containing a hydroxyl group (such as 2-hydroxyethyl (meth)acrylate, 2-hydroxypropyl (meth)acrylate, or 4-hydroxybutyl (meth)acrylate); a monomer having a urethane group such as a compound obtained by reacting a (meth)acrylate containing a hydroxyl group with a residual isocyanate group from the addition of a diisocyanate compound on a hydroxyl group of an alcohol (one or more of alkane diol, polyether diol, polyester diol, and spiroglycol compound); a monomer having a phenyl group such as phenyl (meth)acrylate, benzyl (meth)acrylate, styrene, divinylbenzene, phthalic acid di(meth)acrylate, or terephthalic acid di(meth)acrylate; a monomer having an alkylene oxide group such as pentaerythritolethoxy-modified tetra(meth)acrylate, triethoxylated trimethylolpropane tri(meth)acrylate, ethoxylated pentaerythritol tri(meth)acrylate, ethylene oxide-modified trimethylolpropane (meth)acrylate, propylene oxide-modified trimethylolpropane (meth)acrylate, ethylene oxide-modified glycerol tri(meth)acrylate, propylene oxide-modified glycerol tri(meth)acrylate, tetraethylene glycol di(meth)acrylate, triethylene glycol di(meth)acrylate, polybutylene glycol di(meth)acrylate, polyethylene glycol di(meth)acrylate, polypropylene glycol di(meth)acrylate, polyethoxylated cyclohexanedimethanol di(meth)acrylate, polypropoxylated cyclohexanedimethanol di(meth)acrylate, polyethoxylated bisphenol A di(meth)acrylate, polypropoxylated bisphenol A di(meth)acrylate, polyethoxylated hydrogenated bisphenol A di(meth)acrylate, polypropoxylated hydrogenated bisphenol A di(meth)acrylate, di(meth)acrylate of caprolactone adduct of neopentyl glycol, di(meth)acrylate of caprolactone adduct of butylene glycol, ethylene oxide-modified phosphoric acid (meth)acrylate, hydroxyl-terminated polyethylene glycol mono(meth)acrylate, hydroxyl-terminated polypropylene glycol mono(meth)acrylate, hydroxyl-terminated polybutylene glycol mono(meth)acrylate, alkyl-terminated polyethylene glycol mono(meth)acrylate, alkyl-terminated polypropylene glycol mono(meth)acrylate, or alkyl-terminated polybutylene glycol mono(meth)acrylate; and a monomer having a phenyl group and an alkylene oxide group such as phenoxy polyethylene glycol (meth)acrylate, phenoxy polypropylene glycol (meth)acrylate, or phenoxy polybutylene glycol (meth)acrylate. The monomers (A) can be used alone or in combination of two or more. Among the monomers (A), in terms of superior curing or substrate adhesion, the followings are preferred: a monomer having a urethane group, benzyl (meth)acrylate, pentaerythritol ethoxy-modified tetra(meth)acrylate, triethoxylated trimethylolpropane tri(meth)acrylate, ethoxylated pentaerythritol tri(meth)acrylate, ethylene oxide-modified trimethylolpropane (meth)acrylate, propylene oxide-modified trimethylolpropane (meth)acrylate, ethylene oxide-modified glycerol tri(meth)acrylate, propylene oxide-modified glycerol tri(meth)acrylate, tetraethylene glycol di(meth)acrylate, tripropylene glycol di(meth)acrylate, polybutylene glycol di(meth)acrylate, polyethylene glycol di(meth)acrylate, polypropylene glycol di(meth)acrylate, polyethoxylated bisphenol A di(meth)acrylate, polypropoxylated bisphenol A di(meth)acrylate, polyethoxylated hydrogenated bisphenol A di(meth)acrylate, polypropoxylated hydrogenated bisphenol A di(meth)acrylate, di(meth)acrylate of caprolactone adduct of butylene glycol, hydroxyl-terminated polyethylene glycol mono(meth)acrylate, hydroxyl-terminated polypropylene glycol mono(meth)acrylate, hydroxyl-terminated polybutylene glycol mono(meth)acrylate, alkyl-terminated polyethylene glycol mono(meth)acrylate, alkyl-terminated polypropylene glycol mono(meth)acrylate, alkyl-terminated polybutylene glycol mono(meth)acrylate, phenoxy polyethylene glycol (meth)acrylate, phenoxy polypropylene glycol (meth)acrylate, and phenoxy polybutylene glycol (meth)acrylate. The followings are more preferred: a monomer having a urethane group, benzyl (meth)acrylate, pentaerythritol ethoxy-modified tetra(meth)acrylate, triethoxylated trimethylolpropane tri(meth)acrylate, ethylene oxide-modified trimethylolpropane (meth)acrylate, propylene oxide-modified trimethylolpropane (meth)acrylate, ethylene oxide-modified glycerol tri(meth)acrylate, propylene oxide-modified glycerol tri(meth)acrylate, polybutylene glycol di(meth)acrylate, polyethylene glycol di(meth)acrylate, polypropylene glycol di(meth)acrylate, polyethoxylated bisphenol A di(meth)acrylate, polypropoxylated bisphenol A di(meth)acrylate, polyethoxylated hydrogenated bisphenol A di(meth)acrylate, polypropoxylated hydrogenated bisphenol A di(meth)acrylate, phenoxy polyethylene glycol (meth)acrylate, phenoxy polypropylene glycol (meth)acrylate, and phenoxy polybutylene glycol (meth)acrylate. The followings are even more preferred: a monomer having a urethane group, pentaerythritolethoxy-modified tetra(meth)acrylate, ethylene oxide-modified trimethylol-propane (meth)acrylate, propylene oxide-modified trimethylolpropane (meth)acrylate, ethylene oxide-modified glycerol tri(meth)acrylate, propylene oxide-modified glycerol tri(meth)acrylate, polybutylene glycol di(meth)acrylate, polyethylene glycol di(meth)acrylate, polypropylene glycol di(meth)acrylate, polyethoxylated bisphenol A di(meth)acrylate, polypropoxylated bisphenol A di(meth)acrylate, and polyethoxylated hydrogenated bisphenol A di(meth)acrylate.

(Monomer (B))

Examples of the monomer (B) include: a di(meth)acrylate such as 1,4-butanediol di(meth)acrylate, 1,6-hexanediol di(meth)acrylate, nonanediol di(meth)acrylate, neopentyl glycol di(meth)acrylate, methylpentanediol di(meth)acrylate, diethylpentanediol di(meth)acrylate, tricyclodecanedimethanol hydroxypivalate di(meth)acrylate, cyclohexanedimethanol di(meth)acrylate, neopentyl glycol-modified trimethylolpropane di(meth)acrylate, di(meth)acrylate of an ε-caprolactone adduct of neopentyl glycol hydroxypivalate, di(meth)acrylate of a γ-butyrolactone adduct of neopentyl glycol hydroxypivalate, di(meth)acrylate of a caprolactone adduct of cyclohexanedimethanol, or di(meth)acrylate of a caprolactone adduct of dicyclopentane diol; a mono(meth)acrylate such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, t-butyl (meth)acrylate, n-hexyl (meth)acrylate, cyclohexyl (meth)acrylate, n-octyl (meth)acrylate, 2-ethylhexyl (meth)acrylate, dodecyl (meth)acrylate, stearyl (meth)acrylate, 2-hydroxyethyl (meth)acrylate, 2-hydroxypropyl (meth)acrylate, 4-hydroxybutyl (meth)acrylate, isobornyl (meth)acrylate, norbornyl (meth)acrylate, 2-(meth)acryloyloxymethyl-2-methylbicycloheptane, adamantyl (meth)acrylate, dicyclopentenyl (meth)acrylate, dicyclopentanyl (meth)acrylate, tetracyclododecanyl (meth)acrylate, or cyclohexanedimethanol mono(meth)acrylate; a (meth)acrylamide such as (meth)acrylamide, N,N-dimethyl (meth)acrylamide, N-methylol (meth)acrylamide, N-t-butyl (meth)acrylamide, hydroxyethyl (meth)acrylamide, or methylene bis(meth)acrylamide; and an olefin such as ethylene, propylene, or butene. The monomers (B) can be used alone or in combination of two or more. Among the monomers (B), in terms of satisfying the elastic modulus of the material used as the undercoat layer 12 such that a buckling phenomenon forming an uneven structure is readily generated, di(meth)acrylate and mono(meth)acrylate are preferred, and di(meth)acrylate is more preferred.

(Photopolymerization Initiator (C))

Examples of the photopolymerization initiator (C) include: a carbonyl compound such as benzoin, benzoin monomethyl ether, benzoin isopropyl ether, benzoin isobutyl ether, acetoin, benzyl, benzophenone, p-methoxybenzophenone, diethoxyacetophenone, benzyl dimethyl ketal, 2,2-diethoxyacetophenone, 1-hydroxycyclohexyl phenyl ketone, methylphenyl glyoxylate, ethylphenyl glyoxylate, 2-hydroxy-2-methyl-1 -phenylpropan-1-one, or 2-ethyl anthraquinone; a sulfur compound such as tetramethylthiuram monosulfide or tetramethylthiuram disulfide; and acyl phosphine oxide such as 2,4,6-trimethylbenzoyl diphenylphosphine oxide. The photopolymerization initiators (C) can be used alone or in a combination of two or more. Among them, in terms of superior compatibility with the monomer, a carbonyl compound is preferred, and benzophenone and 1-hydroxycyclohexyl phenyl ketone are more preferred.

In terms of superior adhesion with the inorganic film 13 and satisfying the elastic modulus of the material used as the undercoat layer 12 such that a buckling phenomenon forming an uneven structure is readily generated, the composition ratio of the active energy ray curable composition is preferably such that the monomer (A) takes 10 to 95 mass %, the monomer (B) takes 1 to 70 mass % and the polymerization initiator (C) takes 0.1 to 20 mass % based on the total amount of the active energy ray curable composition, and more preferably such that the monomer (A) takes 30 to 90 mass %, the monomer (B) takes 5 to 60 mass % and the polymerization initiator (C) takes 1 to 10 mass % based on the same total amount.

(Other Components)

The active energy ray curable composition can contain at least one material of, for instance, a photosensitizer, an organic solvent, other various additives (such as leveling agent, anti-foaming agent, anti-sedimentation agent, lubricant, abrasive, rust inhibitor, antistatic agent, light stabilizer, UV absorbent, and polymerization inhibitor), and a polymer (such as polyester-based rein or acrylic resin) as needed without compromising the performance.

Examples of the photosensitizer include methyl 4-dimethylaminobenzoate, ethyl 4-dimethylaminobenzoate, amyl 4-dimethylaminobenzoate, and 4-dimethylaminoacetophenone.

Examples of the organic solvent include: a ketone compound such as acetone, methyl ethyl ketone, cyclohexanone, or methyl isobutyl ketone; an ester compound such as methyl acetate, ethyl acetate, butyl acetate, ethyl lactate, or methoxyethyl acetate; an alcohol compound such as ethanol, isopropanol, or butanol; an ether compound such as diethyl ether, ethylene glycol dimethyl ether, propylene glycol monomethyl ether, diethylene glycol monoethyl ether, diethylene glycol monobutyl ether, dipropylene glycol monomethyl ether, or dioxane; an aromatic compound such as toluene or xylene; and an aliphatic compound such as pentane, hexane, or petroleum naphtha. In the total amount of the active energy ray curable composition, in a case that the active energy ray curable composition contains an organic solvent, the content of the organic solvent is preferably 10 to 80 mass %.

In the case that the active energy ray curable composition contains an organic solvent, before the active energy ray curable composition is cured, the coating film is heated to volatilize the organic solvent. The heating temperature can be suitably selected according to the kind of the organic solvent, and is preferably 40° C. to 150° C. and more preferably 60° C. to 130° C. in terms of thermal history. The heating time can be suitably selected according to the kind of the organic solvent, and is preferably 1 minute to 30 minutes and more preferably 3 to 20 minutes in teens of thermal history. The heating means can include a known heating means such as a heating plate, an IR heater, or warm air.

In terms of readily generating a buckling phenomenon forming an uneven structure, the thickness of the undercoat layer 12 is preferably 0.1 to 100 μm, more preferably 0.2 to 80 μm, and still more preferably 0.5 to 40 μm.

Moreover, the thickness of the undercoat layer 12 is the thickness before the inorganic film 13 is laminated, and is defined as the average thickness in a unit area of 1 mm×l mm.

(Inorganic Film 13)

The inorganic film 13 has an uneven structure at its surface. In terms of readily generating a buckling phenomenon forming an uneven structure, the laminating method of the inorganic film 13 is preferably a sputtering method, an evaporation method, a CVD method or an ion plating method, more preferably a sputtering method, an evaporation method or a CVD method, and still more preferably a sputtering method.

Moreover, the buckling phenomenon refers to the phenomenon occurring when the inorganic film 13 is laminated on the undercoat layer 12, and an uneven structure is formed due to difference in heat shrinkage or difference in elastic modulus of the undercoat layer 12 and the inorganic film 13.

In this embodiment, via the lamination of the inorganic film 13 on the undercoat layer 12 via the above laminating method, an uneven structure is formed on the undercoat layer 12 and the inorganic film 13 in a self-organizing manner.

The sputtering method is the generic term for, for instance, methods in which an inert gas (mainly argon) is introduced into vacuum, and a direct current or alternating current (high frequency) is applied between a substrate and a target at the same time such that ionized inert gas bombards the target and the resulting target material is laminated.

The evaporation method is a generic term for, for instance, methods in which the interior of a container is made into a vacuum state, and heat is applied to a substance such as a metal such that the substance is evaporated, and then the substance such as a metal in vapor state is bombarded in the vacuum to be attached to a substrate, thereby laminating the substance.

The CVD method is a generic term for, for instance, methods in which a raw material gas containing a component of a target substance is provided to a heated substrate, and the substance is laminated via the substrate surface or a gas phase chemical reaction.

The ion plating method is a generic term for, for instance, methods in which a substance such as a metal is heated such that the substance is evaporated and passes through a plasma and carries positive charges, and then the substance is laminated on the substrate carrying negative charges by attracting the evaporated substance such as a metal.

To increase adhesion of the undercoat layer 12 and the inorganic film 13, before the lamination of the inorganic film 13, at least one of a UV ozone treatment, a plasma treatment, and a corona treatment may be applied to the surface of the undercoat layer 12. Moreover, to remove dissolved gas and unreacted monomers, etc. contained in the substrate 11 or the undercoat layer 12, a heat treatment, a vacuum treatment, or a vacuum heat treatment, etc. of the laminate can be applied before the lamination of the inorganic film 13.

The inorganic film 13 includes at least one material of a conductive metal oxide and a conductive metal nitride.

Examples of the at least one material of the conductive metal oxide and the conductive metal nitride, that is, the material of the inorganic film 13, include: metal oxides, such as indium tin oxide (ITO), indium zinc oxide (IZO), fluorine-doped tin oxide (FTO), gallium-doped zinc oxide (GZO), aluminum-doped zinc oxide (AZO), antimony-doped tin oxide (ATO), indium oxide, zinc oxide, tin oxide, titanium oxide, magnesium oxide, zirconium oxide, and silicon dioxide; and metal nitrides, such as indium nitride, gallium nitride, aluminum nitride, zirconium nitride, titanium nitride, and silicon nitride. The materials of the inorganic film 13 can be used alone or in a combination of two or more. Among the materials of the inorganic film 13, in terms of superior hardness or thermal stability, ITO, IZO, indium oxide, zinc oxide, tin oxide, zirconium oxide, indium nitride, gallium nitride, aluminum nitride, zirconium nitride, and titanium nitride are preferred, ITO, IZO, indium oxide, zinc oxide, tin oxide, and zirconium oxide more preferred, and ITO, IZO, indium oxide, and tin oxide are still more preferred.

In a case that the laminate 10 of this embodiment is used as a surface light emitter or a solar cell, since the conductive inorganic layer 13 is included on the surface, the laminate 10 can be directly used as an electrode.

When the inorganic film 13 is formed, any mask can also be used to obtain the laminate 10 for which the inorganic film 13 is only formed at a specific portion. In particular, via the conductive inorganic film 13 formed by masking with an electrode pattern mask, an uneven structure having the conductive inorganic film 13 at the surface can be formed according to the shape of the electrode of the surface light emitter or the solar cell.

In terms of readily generating a buckling phenomenon forming an uneven structure, the thickness of the inorganic film 13 is preferably 0.1 to 1000 nm, more preferably 1 to 800 nm, and still more preferably 5 to 500 nm.

Moreover, the thickness of the inorganic film 13 is defined as the average thickness in a unit area of 1 mm×l mm.

(Uneven Structure of Laminate 10)

The laminate 10 of this embodiment is as described later, wherein in an image obtained by performing Fourier transformation on an image obtained by taking a picture of the surface of the inorganic film 13 with an atomic force microscope, while the azimuth angle from the center of the image toward the direction of 12 o'clock is set to 0°, in approximate curves of 36 brightness value plots obtained by radially plotting the brightness values every 10° from 0°, a maximum value is observed in 18 or more of the approximate curves.

Conditions of taking a picture with an atomic force microscope in this specification can include: obtaining a gray scale image by taking a picture in a range of 50 μm×50 μm with an atomic force microscope in a cantilever dynamic force mode (DFM).

A greater whiteness of the image obtained by taking a picture with an atomic force microscope represents a higher top of the protruding portions of the uneven structure, and a smaller whiteness represents a deeper bottom of the recessed portions of the uneven structure.

Conditions of the Fourier transformation in this specification include obtaining an image by performing a Fourier transformation on the entire obtained gray scale image.

The white portions of the image obtained by performing a Fourier transform represent the pattern and so on of the uneven structure.

Moreover, the center of the image refers to the center of the image obtained from the Fourier transformation, that is, the intersection of the diagonals of the image obtained from the

Fourier transformation.

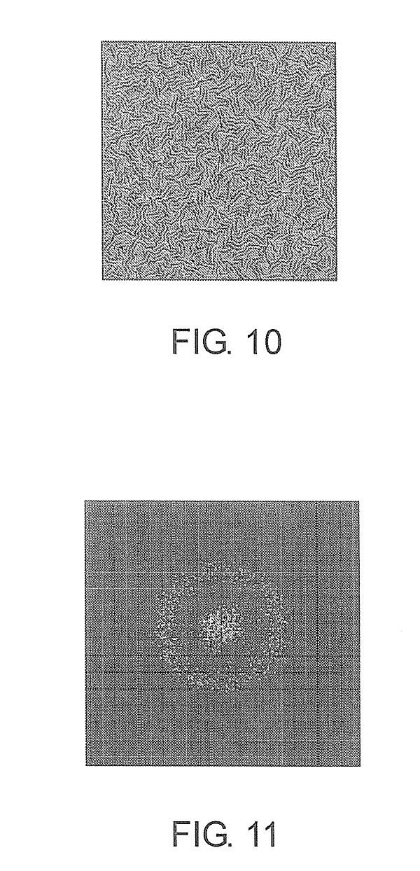

The method for producing an approximate curve in this specification is as described below. First, an image A (FIG. 10) obtained by taking a picture with an atomic force microscope is Fourier transformed into an image B (FIG. 11). Here, the azimuth angle from the center of the image B toward the 12 o'clock direction is set to 0°. Brightness values are radially plotted every 10° from the azimuth angle of 0° to obtain 36 brightness value plots.

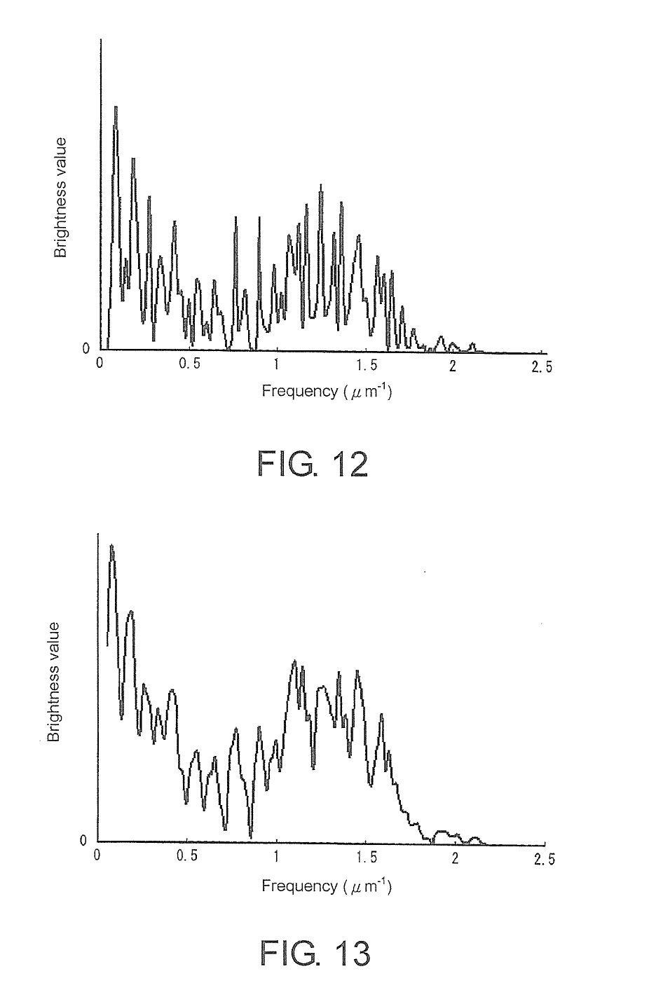

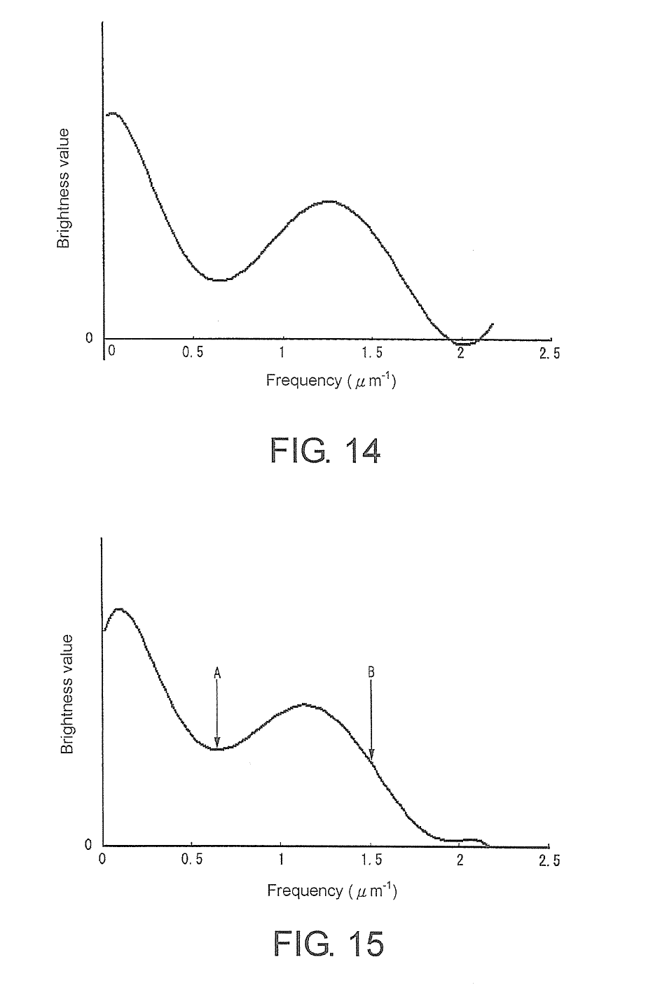

For instance, the plot of brightness values shown in FIG. 12 shows brightness values at the azimuth angle of 90°. Moving averages of each of the obtained 36 brightness value plots are calculated and plotted. For instance, FIG. 13 is obtained by plotting the moving averages calculated from the plot of brightness values shown in FIG. 12. The obtained 36 moving-averaged brightness value plots are fitted by sixth-order polynomial approximate curves, which are used as first sixth-order polynomial approximate curves. For instance, FIG. 14 is a first sixth-order polynomial approximate curve obtained by fitting the plot shown in FIG. 13.

In the 36 first sixth-order polynomial approximate curves of brightness values of the laminate 10 of this embodiment obtained with the above method, in the frequency range of 0.2 to 200 μm⁻¹, a maximum value is observed in 18 or more of the approximate curves, preferably from 24 or more of the same, and more preferably from 30 or more of the same.

The more maximum values are observed in the first sixth-order polynomial approximate curve, the greater the isotropy, and the more the uneven structure at the surface of the laminate 10 represents a structure extended in an irregular direction, wherein the deviation in the angle and the wavelength of the exit or confined light is small.

Moreover, in a first sixth-order polynomial approximate curve, the peak value of the brightness value equal to or less than 1/10 of the maximum brightness value in the frequency range of 0.2 to 200 μm⁻¹ is identified as noise and is not identified as a maximum value.

The 36 brightness value plots are summed, moving averages are calculated and plotted, and the obtained moving-averaged plot is fitted by a sixth-order polynomial approximate curve, which is used as a second sixth-order polynomial approximate curve. In the second approximate curve of the laminate 10 of this embodiment, in the frequency range of 0.2 to 200 μm⁻¹, a frequency at which the brightness value is a minimum value between the frequency of 0.2 μm⁻¹ and a frequency at which the brightness value is a maximum value is set as frequency

A, the largest frequency among frequencies at which the brightness value is half of the maximum value is set as frequency B, and the difference of the reciprocal of frequency A and the reciprocal of frequency B is preferably 0.01 to 10 μm, more preferably 0.05 to 8,μm, still more preferably 0.10 to 7 μm, and even more preferably 0.33 to 5.49 μm.

Moreover, the frequency of the point corresponding to the center of the image obtained from the Fourier transformation is set to 0 μm⁻¹. Moreover, in the second sixth-order polynomial approximate curve, the peak value of the brightness value equal to or less than 1/10 of the maximum brightness value in the frequency range of 0.2 to 200 μm⁻¹ is identified as noise and is not identified as a maximum value.

The second sixth-order polynomial approximate curve is shown in FIG. 15.

Frequency A for which the brightness value is a minimum value between the frequency of 0.2 μm⁻¹ and the frequency at which the brightness value is a maximum value is illustrated by the frequency at point A in FIG. 15.

The largest frequency B in the frequency at which the brightness value is half of the maximum value represents the frequency at point B in FIG. 15.

A greater difference of the reciprocal of frequency A and the reciprocal of frequency B refers to a broader distribution and represents a broad distribution of the period of the uneven structure at the surface of the laminate 10. Thereby, light is effectively diffracted or scattered.

The average pitch of the uneven structure of the surface of the inorganic film 13 of the laminate 10 of this embodiment may be suitably selected according to application, and in terms of readily forming an uneven structure, its value is preferably 0.01 to 10 μm, more preferably 0.1 to 5 μm, still more preferably 0.3 to 4 μm, and even more preferably 1.01 to 3.02 μm.

In a case that the laminate 10 of this embodiment is used as a surface light emitter, in terms of superior light diffraction efficiency, the average pitch of the uneven structure is preferably 0.01 to 10 μm, and more preferably 0.3 to 5 μm.

In the case that the laminate 10 of this embodiment is used as a solar cell, in terms of effectively diffracting or scattering light and reducing deviation in the angle or the wavelength of light, the average pitch of the uneven structure is preferably 0.1 to 10 μm, and more preferably 0.3 to 5 μm.

Moreover, the average pitch of the uneven structure in this embodiment represents the average period of recesses or protrusions of the uneven structure, and refers to the reciprocal of the maximum frequency in the frequency range of 0.2 to 200 μm⁻¹ in a curve obtained by averaging the 36 approximate curves of brightness values obtained by the above method.

The average height of the protruding portions of the uneven structure at the surface of the inorganic film 13 of the laminate 10 of this embodiment can be suitably selected according to application, and in terms of readily forming an uneven structure, the average height is preferably 0.01 to 2 μm, more preferably 0.02 to 1.5 μm, still more preferably 0.03 to 1.2 μm, and even more preferably 0.05 to 0.95 μm.

In a case that the laminate 10 of this embodiment is used as a surface light emitter, in terms of superior light extraction efficiency, the average height of the protruding portions of the uneven structure is preferably 0.01 to 1.5 μm, and more preferably 0.05 to 1.2 μm.

In a case that the laminate 10 of this embodiment is used as a solar cell, in terms of superior light confining efficiency and superior conversion efficiency of the solar cell, the average height of the protruding portions of the uneven structure is preferably 0.03 to 2 μm, and more preferably 0.05 to 1.5 μm.

Moreover, the average height of the protruding portions of the uneven structure can be calculated from the height difference between the top point of a protruding portion and bottom point of an adjacent recessed portion of the profiled cross-section converted from the image obtained using the atomic force microscope. The average height of the protruding portions of the uneven structure is calculated by measuring five points in a range of 50 μm×50 μm.

The surface roughness Ra, the line roughness Ra′, the maximum value Ra′ (max) of line roughness, and the minimum value Ra′(min) of line roughness of the surface of the inorganic film 13 of the laminate 10 of this embodiment preferably satisfy formula (1), and more preferably satisfy formula (2).

Moreover, the surface roughness Ra and the line roughness Ra′ are measured according to JIS B0601-1994.

0.13≦(Ra′(max)−Ra′(min))/Ra≦0. 82 (1)

0.20≦(Ra′(max)−Ra′(min))/Ra≦0.80 (2)

If the inorganic film 13 satisfies formula (1), the uneven structure is neither a regular structure nor an irregular structure, but is a structure in between. That is, the uneven structure is a structure having suitable regularity and suitable irregularity. If the inorganic film 13 satisfies formula (1), then light is effectively diffracted or scattered, and deviation of the angle or the wavelength of light is less.

Accordingly, in the 36 first sixth-order polynomial approximate curves of brightness values of the laminate 10 of this embodiment obtained by the above method, in the frequency range of 0.2 to 200 μm⁻¹, a maximum value is observed in 24 or more of the first sixth-order polynomial approximate curves, and in the second sixth-order polynomial approximate curve, in the frequency range of 0.2 to 200 μm⁻¹, the frequency at which the brightness value is a minimum value between the frequency of 0.2 μm⁻¹ and the frequency at which the brightness value is a maximum value is set as frequency A, the largest frequency among frequencies at which the brightness value is half of the maximum value set as frequency B, and the difference of the reciprocal of frequency A and the reciprocal of frequency B is preferably 0.05 to 8 μm.

In such case, the average pitch of the uneven structure of the surface of the inorganic film 13 may be 0.1 to 5 μm. Further in such case, the average height of the protruding portions of the uneven structure of the surface of the inorganic film 13 may be 0.05 to 1.5 μm.

Further in such case, the elastic modulus of the undercoat layer may be 10 to 1800 MPa.

In the 36 first sixth-order polynomial approximate curves of brightness values of the laminate 10 of this embodiment obtained via the above method, in the frequency range of 0.2 to 200 μm⁻¹, a maximum value is observed in 24 or more of the first sixth-order polynomial approximate curves, and the average pitch of the uneven structure of the surface of the inorganic film 13 is preferably 0.1 to 5 μm.

In such case, the average height of the protruding portions of the uneven structure of the surface of the inorganic film 13 may be 0.05 to 1.5 μm.

Further in such case, the elastic modulus of the undercoat layer may be 10 to 1800 MPa.

In the 36 first sixth-order polynomial approximate curves of brightness values of the laminate 10 of this embodiment obtained via the above method, in the frequency range of 0.2 to 200 μm⁻¹, a maximum value is observed in 24 or more of the first sixth-order polynomial approximate curve, and the average height of the protruding portions of the uneven structure of the surface of the inorganic film 13 may be 0.05 to 1.5 μm.

In such case, the elastic modulus of the undercoat layer may be 10 to 1800 MPa.

In the 36 first sixth-order polynomial approximate curves of brightness values of the laminate 10 of this embodiment obtained by the above method, in the frequency range of 0.2 to 200 μm⁻¹, a maximum value is observed in 30 or more of the first sixth-order polynomial approximate curves, and in the second sixth-order polynomial approximate curve, in the frequency range of 0.2 to 200 μm⁻¹, the frequency at which the brightness value is a minimum value between the frequency of 0.2 μm⁻¹ and the frequency at which the brightness value is a maximum value is set as frequency A, the largest frequency among frequencies at which the brightness value is half of the maximum value is set as frequency B, and the difference of the reciprocal of frequency A and the reciprocal of frequency B is preferably 0.05 to 8 μm.

In such case, the average pitch of the uneven structure of the surface of the inorganic film 13 may be 0.1 to 5 μm.

Further in such case, the average height of the protruding portions of the uneven structure of the surface of the inorganic film 13 may be 0.02 to 1.5 μm.

Further in such case, the elastic modulus of the undercoat layer may be 10 to 1800 MPa.

In the 36 first sixth-order polynomial approximate curves of brightness values of the laminate 10 of this embodiment obtained via the above method, in the frequency range of 0.2 to 200 μm⁻¹,aximum value is observed in 30 or more of the first sixth-order polynomial approximate curves, and the average pitch of the uneven structure of the surface of the inorganic film 13 is preferably 0.1 to 5 μm.

Further in such case, the average height of the protruding portions of the uneven structure of the surface of the inorganic film 13 may be 0.02 to 1.5 μm.

Further in such case, the elastic modulus of the undercoat layer may be 10 to 1800 MPa.

In the 36 first sixth-order polynomial approximate curves of brightness values of the laminate 10 of this embodiment obtained via the above method, in the frequency range of 0.2 to 200 μm⁻¹, a maximum value is observed in 30 or more of the first sixth-order polynomial approximate curves, and the average height of the protruding portions of the uneven structure of the surface of the inorganic film 13 may be 0.02 to 1.5 μm.

In such case, the elastic modulus of the undercoat layer may be 10 to 1800 MPa.

The laminate 10 of this embodiment includes: a substrate of an inorganic material, an undercoat layer disposed on the substrate and formed by curing a urethane acrylate mixture, and an inorganic film disposed on the undercoat layer and having an uneven structure at its surface. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from the center of the image toward the direction of 12 o'clock is set to 0°, and in first approximate curves of 36 brightness value plots obtained by radially plotting the brightness values every 10° from 0°, a maximum is observed in 18 or more of the first approximate curves.

The laminate 10 of this embodiment includes: a glass substrate, an undercoat layer disposed on the substrate and formed by curing a urethane acrylate mixture, and an inorganic film disposed on the undercoat layer and having an uneven structure at its surface. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from a center of the image toward the direction of 12 o'clock is set to 0°. In first approximate curves of 36 brightness value plots obtained by radially plotting the brightness values every 10° from 0°, a maximum value is observed in 18 or more of the first approximate curves.

The laminate 10 of this embodiment includes: a resin substrate, an undercoat layer disposed on the substrate and formed by curing a urethane acrylate mixture, and an inorganic film disposed on the undercoat layer and having an uneven structure at its surface. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from a center of the image toward the direction of 12 o'clock is set to 0°. In first approximate curves of 36 brightness value plots obtained by radially plotting the brightness values every 10° from 0°, a maximum value is observed in 18 or more of the first approximate curves.

The laminate 10 of this embodiment includes: a polyester-based resin substrate, an undercoat layer disposed on the substrate and formed by curing a urethane acrylate mixture, and an inorganic film disposed on the undercoat layer and having an uneven structure at its surface. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from the center of the image toward the direction of 12 o'clock is set to 0°, and in first approximate curves of 36 brightness value plots obtained by radially plotting the brightness values every 10° from 0°, a maximum is observed in 18 or more of the first approximate curves.

The laminate 10 of this embodiment includes: a substrate of an inorganic material, an undercoat layer disposed on the substrate and formed by curing a urethane acrylate mixture, and an inorganic film disposed on the undercoat layer and having an uneven structure at its surface. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from the center of the image toward the direction of 12 o'clock is set to 0°, and in first approximate curves of 36 brightness value plots obtained by radially plotting the brightness values every 10° from 0°, a maximum is observed in 18 or more of the first approximate curves.

The laminate 10 of this embodiment includes: a glass substrate, an undercoat layer disposed on the substrate and formed by curing polyethylene glycol diacrylate, and an inorganic film disposed on the undercoat layer and having an uneven structure at its surface. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from a center of the image toward the direction of 12 o'clock is set to 0°. In first approximate curves of 36 brightness value plots obtained by radially plotting the brightness values every 10° from 0°, a maximum value is observed in 18 or more of the first approximate curves.

The laminate 10 of this embodiment includes: a resin substrate, an undercoat layer disposed on the substrate and farmed by curing polyethylene glycol diacrylate, and an inorganic film disposed on the undercoat layer and having an uneven structure at its surface. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from the center of the image toward the direction of 12 o'clock is set to 0°, and in first approximate curves of 36 brightness value plots obtained by radially plotting the brightness values every 10° from 0°, a maximum is observed in 18 or more of the first approximate curve.

The laminate 10 of this embodiment includes: a polyester-based resin substrate, an undercoat layer formed by curing polyethylene glycol diacrylate, and an inorganic film disposed on the undercoat layer and having an uneven structure at the surface thereof. Moreover, the inorganic film includes at least one material of a conductive metal oxide and a conductive metal nitride. In an image obtained by Fourier transforming an image obtained by using an atomic force microscope to take a picture of the surface of the inorganic film, the azimuth angle from the center of the image toward the direction of 12 o'clock is set to 0°, and in first approximate curves of 36 brightness value plots obtained by radially plotting the brightness values every 10° from 0°, a maximum value is observed in 18 or more of the first approximate curves.

(Applications)

Since the laminate 10 of this embodiment has the conductive inorganic film 13 on the surface and has a corrugated uneven structure at the surface, the laminate 10 can be expected to be used in a wide range of applications. For instance, by using the laminate 10 as an electrode, the electrode can be suitably used in a surface light emitter or a solar cell.

(Electrode)

The laminate 10 in this embodiment can be used as an electrode. The electrode of this embodiment is as shown in FIG. 1, and includes a substrate 11, an undercoat layer 12, and a conductive inorganic film 13.

The conductive inorganic film 13 may include, e.g., a conductive metal oxide, a conductive metal nitride, or a metal that can form a metal film allowing light transmittance.

Examples of the conductive metal oxide and the conductive metal nitride include: metal oxides, such as ITO, IZO, FTO, GZO, AZO, ATO, indium oxide, zinc oxide, tin oxide, titanium oxide, magnesium oxide, zirconium oxide, and silicon dioxide; and metal nitrides, such as indium nitride, gallium nitride, aluminum nitride, zirconium nitride, titanium nitride, and silicon nitride. The conductive metal oxides and conductive metal nitrides may be used alone or in combination of two or more. Among the conductive metal oxides and the conductive metal nitrides, in terms of superior conductivity, ITO, IZO, indium oxide, zinc oxide, tin oxide, zirconium oxide, indium nitride, gallium nitride, aluminum nitride, zirconium nitride, and titanium nitride are preferred, ITO, IZO, indium oxide, tin oxide, and indium nitride are more preferred, and ITO, IZO, indium oxide, and tin oxide are still more preferred.

Examples of the metal capable of forming a metal thin film capable of light transmittance include gold, platinum, silver, copper, and aluminum.

The conductive inorganic film 13 can be one layer or include two or more layers.

In terms of superior conductivity, the thickness of the conductive inorganic film 13 is preferably 10 nm or more, and more preferably 50 nm or more. Moreover, in terms of superior light transmittance, the thickness of the conductive inorganic film 13 is preferably 1000 nm or less, and more preferably 500 nm or less. Moreover, the conductive inorganic film 13 may be measured by using a stepped·surface roughness·fine-shape measuring apparatus.

The thickness of the conductive inorganic film 13 of this embodiment is defined as the average thickness in a unit area of 1 mm×1 mm.

The electrode of this embodiment can be used in, for instance, the electrode of an EL element or the electrode of a solar cell.

(Surface Light Emitter)

The surface light emitter in this embodiment may be, e.g., a surface light emitter including an EL element, wherein the EL element is disposed on a substrate having an uneven structure at the surface. The EL element at least includes: a first electrode, a second electrode disposed separately from the first electrode, and a light-emitting layer between the first electrode and the second electrodes. FIG. 2 is a cross-sectional view of an example of a surface light emitter of this embodiment. A surface light emitter 20 includes a laminate 210, a light-emitting layer 21, and a second electrode 22. The laminate 210 includes a substrate 11, an undercoat layer 12, and a first electrode 23. The laminate 10 can be used as the laminate 210. That is, by having both the substrate 11 with an uneven structure at the surface and the first electrode 23 disposed on the surface of the uneven structure, the laminate 10 can be used as the laminate 210.

Moreover, the substrate 11 having an uneven structure at the surface thereof can be used for the laminate 10. That is, as shown in FIG. 3, a surface light emitter 20′ can include a laminate 211, a first electrode 23, a light-emitting layer 21, and a second electrode 22. The laminate 211 includes a substrate 11, an undercoat layer 12, and an inorganic film 13.

Since the period of the uneven structure of each of the surface light emitter 20 including the laminate 210 and the surface light emitter 20′ including the laminate 211 of this embodiment has a broad distribution and the uneven structure has a structure extended in an irregular direction (that is, a corrugated uneven structure), the corrugated uneven structures effectively diffract or scatter light such that deviation in the angle or the wavelength of light is small. Therefore, in comparison to the conventional surface light emitter, the light extraction efficiency is superior, and a wide extent can be uniformly irradiated.

The surface light emitter can be an EL element itself To further increase the light extraction efficiency, it is also possible to dispose a light extraction component on the surface of the light exit side of the EL element and use the structure as a surface light emitter.

The light extraction component may include a known light extraction component. Examples thereof include: a component having an uneven structure, such as a prism sheet, a cylindrical lens sheet, or a microlens sheet; and a component coated with fine particles.

The material composition, the shape of the uneven structure, the size of the uneven structure, the arrangement of the uneven structure, the filling ratio of the uneven structure and so on of the component having an uneven structure only need to be suitably selected according to the orientation distribution of the EL element, etc. Moreover, the material composition of the component having an uneven structure may contain light diffusing particles as required.

The method for forming a component coated with a microparticle can include, for instance: coating a microparticle via dispersion in a dispersion medium and drying the same; and coating a curable composition containing a microparticle and curing the same via, e.g., UV or heat.

(EL Element)

EL elements include bottom-emission type and top-emission type EL elements. The laminate 210 of this embodiment may also be used in any type of EL element.

The bottom-emission type refers to the type of EL element in which a material forming the EL element is laminated on a support substrate to fabricate the element and light exits via the support substrate. The top-emission type refers to the type of EL element in which a material forming the EL element is laminated on a support substrate to fabricate the element and light exits from the side opposite to the support substrate.

(First Electrode)

The first electrode 23 may be an anode, and may alternatively be a cathode. In general, the first electrode 23 is configured as an anode.

The material of the first electrode 23 may be, for instance, a conductive metal oxide, a conductive metal nitride, a conductive organic polymer, or a metal capable of forming a metal thin film capable of light transmittance.

Examples of the conductive metal oxide and the conductive metal nitride include: metal oxides, such as ITO, IZO, FTO, GZO, AZO, ATO, indium oxide, zinc oxide, tin oxide, titanium oxide, magnesium oxide, zirconium oxide, and silicon dioxide; and metal nitrides, such as indium nitride, gallium nitride, aluminum nitride, zirconium nitride, titanium nitride, and silicon nitride. The conductive metal oxides and conductive metal nitrides can be used alone or in combination of two or more. In terms of superior conductivity, among the conductive metal oxides and the conductive metal nitrides, ITO, IZO, indium oxide, zinc oxide, tin oxide, zirconium oxide, indium nitride, gallium nitride, aluminum nitride, zirconium nitride, and titanium nitride are preferred, ITO, IZO, indium oxide, tin oxide, and indium nitride are more preferred, and ITO, IZO, indium oxide, and tin oxide are still more preferred. It is also possible that a conductive metal oxide or a conductive metal nitride is directly used for the inorganic film 13 of the laminate of this embodiment.

Examples of the conductive organic polymer include: polyaniline and derivatives thereof, polythiophene, and poly-3,4-ethylenedioxythiophene-polystyrenesulfonate (PEDOT-PSS) and derivatives thereof.

Examples of the metal capable of forming a metal thin film capable of light transmittance include gold, platinum, silver, copper, and aluminum.

The first electrode 23 may be one layer, or may include two or more layers.

The first electrode 23 has an uneven structure at the surface thereof.

In terms of superior conductivity, the thickness of the first electrode 23 is preferably 10 nm or more, and more preferably 50 nm or more. Moreover, in terms of superior light transmittance, the thickness of the first electrode is preferably 1000 nm or less, and more preferably 500 nm or less. Moreover, the thickness of the first electrode can be measured by using a step difference/surface roughness/fine shape measuring apparatus.

The thickness of the first electrode 23 of this embodiment is defined as the average thickness in a unit area of 1 mm×l mm.

(Second Electrode)

The second electrode 22 may be a cathode, and may alternatively be an anode. In general, the second electrode 22 is configured as a cathode.

Examples of the material of the second electrode 22 include: metals, such as lithium, sodium, potassium, rubidium, cesium, beryllium, magnesium, calcium, strontium, barium, aluminum, scandium, vanadium, zinc, yttrium, indium, cerium, samarium, europium, terbium, or ytterbium; alloys formed by combining two or more of the metals; metal salts, such as fluorides of the metals; or alloys of one or more of the metals and one or more of gold, silver, platinum, copper, manganese, titanium, cobalt, nickel, tungsten, and tin. Examples of the alloys include: a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

The second electrode 22 may be one layer, or may include two or more layers.

In terms of superior conductivity, the thickness of the second electrode 22 is preferably 5 nm or more, and more preferably 10 nm or more. Moreover, in terms of superior durability, the thickness of the second electrode 22 is preferably 1000 nm or less, and more preferably 300 nm or less. Moreover, the thickness of the second electrode 22 can be measured by using a step difference/surface roughness/fine shape measuring apparatus.

The thickness of the second electrode 22 of this embodiment is defined as the average thickness in a unit area of 1 mm×1 mm.

It is also possible that one of the first electrode and the second electrode 22 is transmissive and the other is reflective. Alternatively, both of them are transmissive.

(Light-Emitting Layer)

In a case that the surface light emitter is an organic EL element, the light-emitting layer 21 contains a light-emitting material of an organic compound. In a case that the surface light emitter is an inorganic EL element, the light-emitting layer 21 contains a light-emitting material of an inorganic compound.

Examples of the light-emitting material of an organic compound include: a carbazole derivative (such as 4,4′-N,N′-dicarbazole-diphenyl) being a host compound as a phosphorescent compound doped with an iridium complex (tris(2-phenylpyridine)iridium), a metal complex of 8-hydroxyquinoline or a derivative thereof, such as tris(8-hydroxyquinoline)aluminum; and other known light-emitting materials.

In addition to a light-emitting material, the light-emitting layer 21 may also contain, for instance, a hole transport material or an electron transport material.

The light-emitting layer 21 may be one layer or may include two or more layers. For instance, in a case that the surface light emitter is used for white organic EL illumination, the light-emitting layer 21 may be configured as a laminate structure having a blue light-emitting layer, a green light-emitting layer, and a red light-emitting layer.

The thickness of the light-emitting layer 21 is preferably 1 to 100 nm, more preferably 10 to 50 nm. Moreover, the thickness of the light-emitting layer 21 can be measured by using a step difference/surface roughness/fine shape measuring apparatus.

The thickness of the light-emitting layer 21 of this embodiment is defined as the average thickness in a unit area of 1 mm×1 mm

(Method for Producing EL Element)

The EL element is produced by, for instance, process 1 (steps (A) to (B)) or process 2 (steps (a) to (c)). Among the methods for producing an EL element, in terms of reducing the number of steps to obtain the EL element, step 1 is preferred.

(Process 1)

Process 1 including steps (A) to (B) for forming the EL element contained in the surface light emitter 20 as shown in FIG. 2 is described below.

Step (A): the material of the light-emitting layer 21 is laminated on the surface of the first electrode 23 of the laminate 210 of this embodiment to form the light-emitting layer 21.

Step (B): after step (A), the material of the second electrode 22 is laminated to form the second electrode 22.

(Process 2)

Process 2 including steps (a) to (c) for forming the EL element contained in the surface light emitter 20′ as shown in FIG. 3 is described below.

Step (a): the material of the first electrode is laminated on the surface of the inorganic film 13 of the laminate 210 of this embodiment to form the first electrode 23.

Step (b): after step (a), the material of the light-emitting layer 21 is laminated to form the light-emitting layer 21.

Step (c): after step (b), the material of the second electrode 22 is laminated to form the second electrode 22.

Examples of the laminating method of step (a) include a sputtering method, an evaporation method, and an ion plating method. Among the methods, in terms of readily forming the first electrode, a sputtering method is preferred. To increase the adhesion between the uneven structure and the first electrode, before step (a), at least one of treatments such as a UV ozone treatment, a plasma treatment and a corona treatment may be applied to the surface of the inorganic film 13 of the laminate 211. Moreover, to remove dissolved gas, unreacted monomers and so on contained in the laminate 10, before step (a), at least one of treatments such a heat treatment, a vacuum treatment and a vacuum heat treatment may be applied thereto.

Examples of the laminating method of step (A) or (b) include a sputtering method, an evaporation method and an ion plating method. Among the laminating methods, in the case that the material of the light-emitting layer 21 is an organic compound, in terms of readily forming the light-emitting layer 21, an evaporation method is preferred.

Examples of the laminating method of step (B) or (c) include a sputtering method, an evaporation method and an ion plating method. Among the methods, in cases that the material of the light-emitting layer 21 is an organic compound, in terms of not damaging the layer 21 and readily forming the second electrode 22, an evaporation method is preferred.

In a case that other functional layers are disposed between the first electrode 23 and the light-emitting layer 21 or between the second electrode 22 and the light-emitting layer 21, the other functional layers may also be formed via the same method and conditions as the light-emitting layer 21 before or after the forming of the light-emitting layer 21.

Examples of the other functional layers include: a hole injection layer, a hole transport layer, a hole blocking layer, an electron transport layer, and an electron injection layer.

(Hole Injection Layer)

The hole injection layer is a layer containing a hole injection material.

Examples of the hole injection material include: a transition metal oxide such as molybdenum oxide or vanadium oxide, copper phthalocyanine, a conductive organic polymer, and other known organic hole injection materials.

In the case of a transition metal oxide, the thickness of the hole injection layer is preferably 2 to 20 nm, more preferably 3 to 10 nm. In the case of an organic hole injection material, the thickness of the hole injection layer is preferably 1 to 100 nm, more preferably 10 to 50 nm.

(Hole Transport Layer)

The hole transport layer is a layer containing a hole transport material.

Examples of the hole transport material include: triphenyldiamine compounds (such as 4,4′-bis(m-tolylphenylamino)biphenyl), and other known hole transport materials. The thickness of the hole injection layer is preferably 1 to 100 nm, more preferably 10 to 50 nm.

(Hole Blocking Layer)

The hole blocking layer is a layer containing a hole blocking material.

Examples of the hole blocking material include: 2,9-dimethyl-4,7-diphenyl-1,10-phenanthroline, and other known hole blocking materials. The thickness of the hole injection layer is preferably 1 to 100 nm, more preferably 5 to 50 nm.

(Electron Transport Layer)

The electron transport layer is a layer containing an electron transport material.

Examples of the electron transport material are metal complexes of 8-hydroxyquinoline or derivatives thereof, oxadiazole derivatives, and other known electron transport materials. The thickness of the electron transport layer is preferably 1 to 100 nm, more preferably 10 to 50 nm.

(Electron Injection Layer)

The electron injection layer is a layer containing an electron injection material.

Examples of the electron injection material include: an alkali metal compound (such as lithium fluoride), an alkaline earth metal compound (such as magnesium fluoride), a metal (such as strontium), and other known electron injection materials. The thickness of the electron injection layer is preferably 0.1 to 50 nm, more preferably 0.2 to 10 nm

Moreover, the thickness of each of the other functional layers can be measured by using a step difference/surface roughness/fine shape measuring apparatus.

(Solar Cell)

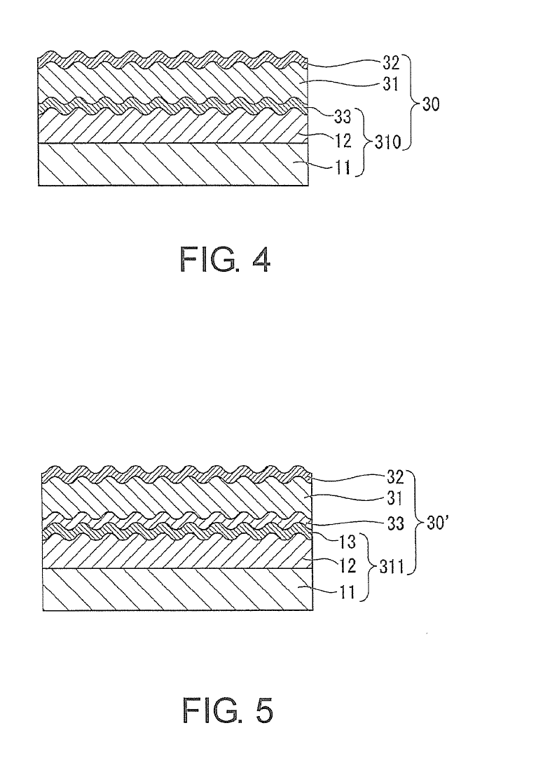

The solar cell may include, for instance, a substrate having an uneven structure at the surface, a transparent electrode disposed on the surface of the uneven structure, a photoelectric conversion layer, and a back electrode. FIG. 4 is a cross-sectional view of an example of a solar cell of this embodiment. The solar cell 30 includes a laminate 310, a photoelectric conversion layer 31, and a back electrode 32. The laminate 310 includes a substrate 11, an undercoat layer 12, and a transparent electrode 33. That is, by having both the substrate 11 having an uneven structure at the surface and the transparent electrode 33 disposed on the surface of the uneven structure, the laminate 10 can be used as the laminate 310.

Moreover, the laminate 10 can be used as the substrate 11 having an uneven structure at its surface. That is, as shown in FIG. 5, a solar cell 30′ may include a laminate 311, a transparent electrode 33, a photoelectric conversion layer 31, and a back electrode 32. The laminate 311 includes a substrate 11, an undercoat layer 12, and an inorganic film 13.

Since the period of the uneven structure of each of the solar cell 30 including the laminate 310 and the solar cell 30′ including the laminate 311 of this embodiment has a broad distribution and the uneven structure of each of them has a structure extended in an irregular direction (that is, a corrugated uneven structure), the corrugated uneven structures effectively diffract or scatter light. Since light of a broad range of wavelengths enters the solar cell, and light enters the solar cell from an inclined direction via the diffraction or scattering, the optical path length in the solar cell is increased. As a result, the light confining efficiency of the solar cell is increased, and the conversion efficiency of the solar cell is increased.

The material of the substrate 11 only needs to be light transmitting. Examples thereof include glass, a polyester-based resin, an acrylic-based resin, a carbonate-based resin, a styrene-based resin, a cellulose-based resin, and an olefin-based resin. The substrate materials can be used alone or be laminated in two or more. The substrate 11 of the laminate 10 of this embodiment can also be directly used as the substrate.

Examples of the material of the transparent electrode 33 include: metal oxides, such as ITO, IZO, FTO, GZO, AZO, ATO, indium oxide, zinc oxide, tin oxide, titanium oxide, magnesium oxide, zirconium oxide, and silicon dioxide; and metal nitrides, such as indium nitride, gallium nitride, aluminum nitride, zirconium nitride, titanium nitride, and silicon nitride. The conductive metal oxides and conductive metal nitrides can be used alone or in combination of two or more. Among the conductive metal oxides and the conductive metal nitrides, in terms of superior conductivity, ITO, IZO, indium oxide, zinc oxide, tin oxide, zirconium oxide, indium nitride, gallium nitride, aluminum nitride, zirconium nitride, and titanium nitride are preferred, ITO, IZO, indium oxide, tin oxide, and indium nitride are more preferred, and ITO, IZO, indium oxide, and tin oxide are still more preferred. The inorganic film 13 of the laminate 10 of this embodiment can also be directly used for the transparent electrode 33.

The photoelectric conversion layer 31 is a layer including a thin-film semiconductor. Examples of the thin-film semiconductor include: an amorphous silicon-based semiconductor, a microcrystalline silicon-based semiconductor, compound semiconductors (such as chalcopyrite-based semiconductor and CdTe-based semiconductor), and organic semiconductors.

Examples of the material of the back electrode 32 include: a metal thin film such as a film of gold, platinum, silver, copper, or aluminum, and a conductive metal oxide such as ITO, IZO, indium oxide, zinc oxide, or tin oxide.

Examples of the lamination method of the transparent electrode 33, the photoelectric conversion layer 31, and the back electrode 32 include a sputtering method, an evaporation method, and an ion plating method. To increase adhesion of each layer, before lamination, at least one of treatments such as a UV-O₃ treatment, a plasma treatment and a corona treatment may be applied. Moreover, to remove dissolved gas unreacted monomers and so on contained therein, before lamination, at least one of treatments such as a heat treatment, a vacuum treatment and a vacuum heat treatment may be applied to the uneven substrate.

Moreover, the thickness of each of the transparent electrode 33, the photoelectric conversion layer 31, and the back electrode 32 may be measured using a step difference/surface roughness/fine shape measuring apparatus.

If required, a protective resin layer may also be disposed on the surface of the light incident surface side of each of the solar cell 30 and the solar cell 30′. Alternatively, a back sheet may be disposed on the surface of the resin layer.

### EXAMPLES

In the following, aspects of the invention are specifically described with examples, but the aspects of the invention are not limited to the examples.

Moreover, “parts” and “%” in the examples refer to “parts by mass” and “mass %”.

(Measurement of Elastic Modulus)

An active energy ray curable composition for forming an undercoat layer was added dropwise (200 μm thick) on a glass substrate (trade name “Eagle XG”, made by Corning Inc., 5 cm long, 5 cm wide, and 0.7 mm thick) having been subjected to excimer cleaning (172 nm UV lamp, made by M.D. Excimer Inc.). After heating at 60° C. on a heating plate for 10 minutes, the active energy ray curable composition was irradiated with UV light (integrated amount of light: 1000 mJ/cm²) to be cured.

For the glass substrate having thereon the cured active energy ray curable composition, a micro-hardness tester (machine model “Fischerscope HM2000”, made by Fischer Corporation) was used to measure the elastic modulus at 5 locations under the conditions of a force of 50 mN/10 sec and a creep time of 5 sec, and the average value thereof was taken as the elastic modulus of the material of the undercoat layer.

(Measurement of Surface Shape)

The surface shape of the laminate recited in each of Examples 1 to 22 was measured by the following method. For each laminate, 5 points in a range of 50, μm×50 μm were measured by using an atomic force microscope (machine model “VN-8010”, made by Keyence Corporation, in cantilever DFM/SS mode).

Using the full range of the 5 points measured in a range of 50 μm×50, μm as the analysis range, arithmetic averages of the surface roughness Ra, maximum height Ry, ten-point average height Rz, and root mean square surface roughness RMS of the 5 points were calculated according to the surface roughness measurement of JIS B0601-1994.

For the 5 points measured in a range of 50 μm×50 μm, according to the line roughness measurement of JIS B0601-1994, a measurement line having a width of 45 μm was drawn, the measurement line was rotated as a base shaft in a unit of 15°, with its center as the center of the rotation, to draw 12 measurement lines having a width of 45 μm as well, and measurement was performed on the 12 measurement lines. An average value Sm of 5 points of the average unevenness interval in the total of 12 measurement lines was calculated.

The surface shape measurement was performed on the laminate obtained in each of Examples 1 to 22. For the laminate obtained in each of Comparative Examples 1 to 9, since the surface of the laminate was smooth, measurement of body shape was not readily performed.

(Measurement of Resistance Value)

The measurement of the conductivity of the inorganic film of the laminate described in Examples 1 to 22 and Comparative Examples 1 to 9 was performed with a resistivity meter (“Loresta GP”, by Mitsubishi Chemical Analytech) and 4-probe heads according to JIS K7194. Moreover, the average value obtained from 10 measurements was used as the resistance value.

(Analysis of Surface Shape)

The analysis of surface shape of the laminate described in each of Examples 1 to 22 was performed as follows. For each laminate, 5 points were pictured in a range of 50 μm×50 μm by using an atomic force microscope (“VN-8010”, made by Keyence Corporation, in cantilever DFM/SS mode), thereby obtaining a gray scale image. Fourier transformation was performed on the obtained gray scale image to obtain an image. For the obtained image, brightness values were radially plotted every 10° from the center of the image, and then the obtained 36 brightness value plots were made into first sixth-order polynomial approximate curves. In the first sixth-order polynomial approximate curve of the obtained 36 brightness value plots, in the frequency range of 0.2 to 200 μm⁻¹, observation of a maximum value in a number of the first sixth-order polynomial approximate curves was confirmed.

Moreover, in the curve obtained by averaging the first sixth-order polynomial approximate curves of the 36 brightness value plots, the frequency at which the brightness value is a minimum between the center in the frequency range of 0.2 to 200 μm⁻¹ and a maximum of the brightness values was set as frequency A, the largest frequency among the frequencies at which the brightness value is half of the maximum was set as frequency B, and the difference between the reciprocal of frequency A and the reciprocal of frequency B was calculated.

Moreover, the average pitch of the uneven structure is the reciprocal of the frequency at the maximum in the frequency range of 0.2 to 200 μm⁻¹ in the second sixth-order polynomial approximate curve obtained by averaging the 36 first sixth-order polynomial approximate curve of brightness values.

Therefore, the average height of the protruding portions of the uneven structure was obtained by measuring 5 locations in the height difference between the top of a protruding portion and the bottom of an adjacent recessed portion of the cross-section profiled according to the image pictured by an atomic force microscope.

(Light Extraction Efficiency)

The light extraction efficiency of the surface light emitter (OEL light-emitting apparatus) obtained in each of Example 23, Comparative Example 10, and Comparative Example 11 was performed with the following method. A light-shielding sheet having a thickness of 0.1 mm and a hole with a diameter of 10 mm was disposed on the surface light emitter, and the surface light emitter was disposed in the sample opening portion of an integrating sphere (made by Labsphere Inc.; size: 6 in.) Under such state, light emitted from the hole with a diameter of 10 mm of the light-shielding sheet when lighting was provided by supplying a current of 10 mA to the OEL light-emitting apparatus (surface light emitter) was measured with a spectrometer measuring instrument (beam splitter: “PMA-12” made by Hamamatsu Photonics; software: “basic software U6039-01 ver.3.3.1 for PMA”), then correction was performed via a standard luminosity curve, and then the number of photons of the surface light emitter was calculated.

The ratio of the number of photons of the surface light emitter obtained when the number of photons of the surface light emitter obtained in Comparative Example 10 was set to 100% was taken as the light extraction efficiency.

### Example 1

A urethane acrylate mixture (trade name: “Diabeam UM-8002”, by Mitsubishi Rayon Co., Ltd.) used as the active energy ray curable composition for forming an undercoat layer was spin coated (rotation speed: 500 rpm, thickness: 3 μm) on a glass substrate (trade name “Eagle XG”, made by Coming Inc.; 5 cm long, 5 cm wide, and 0 7 mm thick) having been subjected to an excimer cleaning (172 nm UV lamp, made by M.D. Excimer Inc.) was performed. After the glass substrate on which a urethane acrylate mixture was spin coated was heated at 60° C. on a heating plate for 10 min, the active energy ray curable composition was irradiated with UV light (integrated amount of light: 1000 mJ/cm²) to be cured. An undercoat layer was laminated on the glass substrate via the above operation.

Then, on the undercoat layer, ITO of 20 nm was laminated with an RF sputtering apparatus (machine model “SVC-700RF”, made by Sanyu Electronic, Inc.) to obtain a laminate.

The surface shape and so on of the obtained laminate are shown in Table 1.

### Examples 2 to 6

Except that the lamination amount of ITO was set to the thickness shown in Table 1, the same operation as Example 1 was performed to obtain laminates. A laminate in which the ITO thickness was set to 40 nm was used in Example 2. A laminate in which the ITO thickness was set to 60 nm was used in Example 3. A laminate in which the ITO thickness was set to 80 nm was used in Example 5. A laminate in which the ITO thickness was set to 100 nm was used in Example 6.

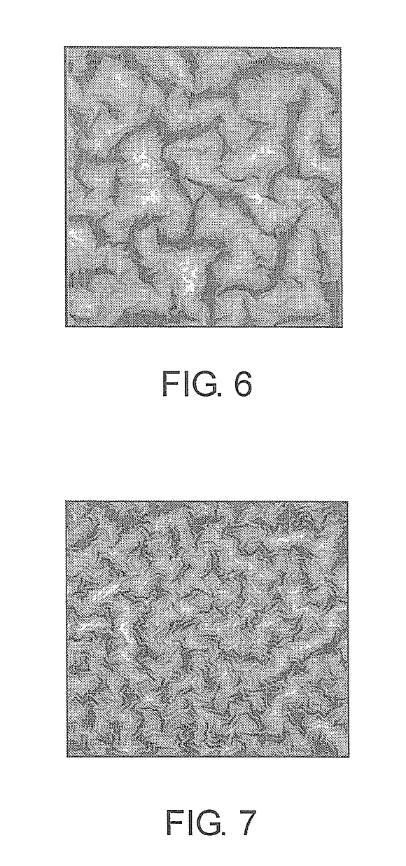

The surface shape and so on of the obtained laminates are shown in Table 1. Moreover, an image (50 μm×50 μm) obtained by taking a picture of the laminate obtained in Example 5 with an atomic force microscope is shown in FIG. 6.

### Comparative Example 1

Except that ITO of 100 nm instead of an undercoat layer was laminated on a glass substrate having been subjected to an excimer cleaning, the same operation as example 1 was performed. However, a laminate having an uneven structure at the surface was not obtained.

The resistance value of the obtained laminate is shown in Table 1.

### Example 7

Except that ITO of 100 nm was laminated on a polyethylene terephthalate resin substrate (trade name: “Cosmoshine A4100”, produced by Toyobo Co., Ltd., 188 μm thick), the same operation as Example 1 was performed to obtain the laminate.

The surface shape and so on of the obtained laminate are shown in Table 1.

### Examples 8 and 9

Except that the material of the inorganic film was set to IZO and the lamination amount of the inorganic film was set to the thickness shown in Table 1, the same operation as Example 1 was performed to obtain laminates. A laminate in which the IZO thickness was 50 nm was used in Example 8. A laminate in which the IZO thickness was 100nm was used in Example 9.

The surface shape and so on of the obtained laminates are shown in Table 1.

### Examples 10 and 11

Except that a urethane acrylate mixture (trade name “Diabeam UM-8003-1”, by Mitsubishi Rayon Co., Ltd.) was laminated in a thickness of 8 μm as the active energy ray curable composition for forming the undercoat layer, the material of the inorganic film was set to IZO, and the lamination amount of the inorganic film was set to the thickness shown in Table 1, the same operation as Example 1 was performed to obtain laminates. A laminate in which the IZO thickness was set to 50 nm was used in Example 10. A laminate in which the IZO thickness was set to 100 nm was used in Example 11.

The surface shape and so on of the obtained laminate are shown in Table 1. Moreover, an image (50 μm×50 μm) obtained by taking a picture of the laminate obtained in Example 10 with an atomic force microscope is shown in FIG. 7.

### Comparative Example 2

Except that IZO of 100 nm instead of an undercoat layer was laminated on a glass substrate having been subjected to an excimer cleaning, the same operation as Example 8 was performed. However, a laminate having an uneven structure at the surface was not obtained.

The resistance value of the obtained laminate is shown in Table 1.

### Examples 12 and 13

Except that the material of the inorganic film was set to ZrO₂ (zirconium oxide, produced by Sanyu Electronic Inc.) and the lamination amount of the inorganic film was set to the thickness shown in Table 1, the same operation as Example 1 was performed to obtain laminates. A laminate in which the ZrO₂ thickness was set to 5 nm was used in Example 12. A laminate in which the ZrO₂ thickness was set to 36 nm was used in Example 13.

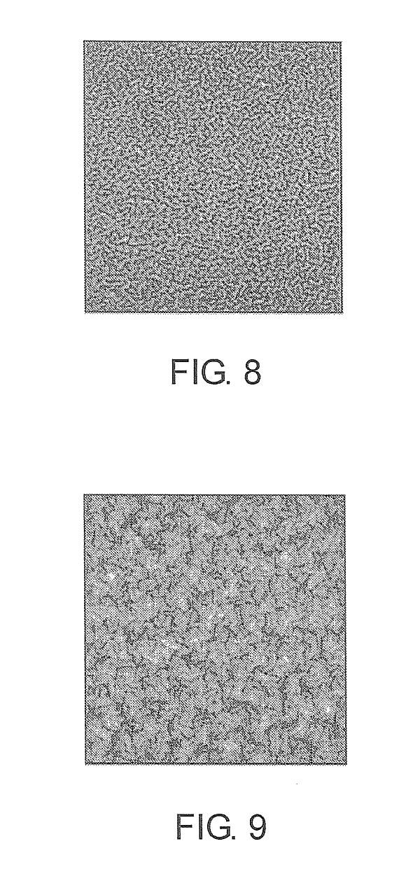

The surface shape and so on of the obtained laminates are shown in Table 1. Moreover, an image (50 μm×050 μm) obtained by taking a picture of the laminate obtained in Example 12 with an atomic force microscope is shown in FIG. 8.

### Comparative Example 3

Except that ZrO₂ of 5 nm instead of an undercoat layer was laminated on a glass substrate having been subjected to an excimer cleaning, the same operation as Example 12 was performed. However, a laminate having an uneven structure at the surface was not obtained.

The resistance value of the obtained laminate is shown in Table 1.

### Example 14

Except that the material of the inorganic film was set to SiO₂ (silicon oxide, produced by Sanyu Electronic Inc.) and the lamination amount of the inorganic film was set to the thickness in Table 1, the same operation as Example 1 was performed to obtain an uneven substrate.

The surface shape and so on of the obtained laminate are shown in Table 1.

### Comparative Example 4

Except that SiO₂ of 10 nm instead of an undercoat layer was laminated on a glass substrate having been subjected to an excimer cleaning, the same operation as Example 14 was performed. However, a laminate having an uneven structure at the surface was not obtained.

The resistance value of the obtained laminate is shown in Table 1.

### Example 15

On the inorganic film of the laminate obtained in Example 12, ITO of 100 nm was laminated with an RF sputtering apparatus to obtain a laminate on which two inorganic films were laminated.

The surface shape and so on of the obtained laminate are shown in Table 2. Moreover, an image (50 μm×50 μm) obtained by taking a picture of the obtained laminate with an atomic force microscope is shown in FIG. 9.

### Example 16

On the inorganic film of the laminate obtained in Example 12, ITO of 200 nm was laminated with an RF sputtering apparatus to obtain a laminate on which two inorganic films were laminated.

The surface shape and so on of the obtained laminate are shown in Table 2.

### Comparative example 5

On the inorganic film of the substrate obtained in Comparative Example 3, ITO of 100 nm was laminated with an RF sputtering apparatus to obtain a laminate on which two inorganic films were laminated.

The resistance value of the obtained laminate is shown in Table 2.

### Comparative Example 6

On the inorganic film of the substrate obtained in Comparative Example 3, ITO of 200 nm was laminated with an RF sputtering apparatus to obtain a laminate on which two inorganic films were laminated.

The resistance value of the obtained substrate is shown in Table 2.

### Example 17

On the inorganic film of the laminate obtained in Example 14, ITO of 100 nm was laminated with an RF sputtering apparatus to obtain a laminate on which two inorganic films were laminated.

The surface shape and so on of the obtained laminate are shown in Table 2.

### Example 18

On the inorganic film of the laminate obtained in Example 14, IZO of 100 nm was laminated with an RF sputtering apparatus to obtain a laminate on which two inorganic films were laminated.

The surface shape and so on of the obtained laminate are shown in Table 2.

### Comparative Example 7

On the inorganic film of the substrate obtained in Comparative Example 4, ITO of 100 nm was laminated with an RF sputtering apparatus to obtain a substrate on which two inorganic films were laminated.

The resistance value of the obtained substrate is shown in Table 2.

### Comparative Example 8

On the inorganic film of the substrate obtained in Comparative Example 4, IZO of 100 nm was laminated with an RF sputtering apparatus to obtain a substrate on which two inorganic films were laminated.

The resistance value of the obtained substrate is shown in Table 2.

### Example 19

Except that polyethylene glycol diacrylate (trade name: “A-200”, made by Shin Nakamura

File: 47464usf True translation

Chemical Co., Ltd.) was laminated in a thickness of 2 μm as the active energy ray curable composition for forming an undercoat layer, the same operation as Example 2 was performed to obtain a laminate.

The surface shape and so on of the obtained laminate are shown in Table 2.

### Example 20

Except that polyethylene glycol diacrylate (trade name: “A-400”, made by Shin Nakamura Chemical Co., Ltd.) was laminated in a thickness of 2 μm as the active energy ray curable composition for foaming an undercoat layer, the same operation as Example 2 was performed to obtain a laminate.

The surface shape and so on of the obtained laminate are shown in Table 2.

### Example 21

Except that polyethylene glycol diacrylate (trade name “A-1000”, made by Shin Nakamura Chemical Co., Ltd.) was laminated in a thickness of 2 μm as the active energy ray curable composition for forming an undercoat layer, the same operation as Example 2 was performed to obtain a laminate.

The surface shape and so on of the obtained laminate are shown in Table 2. Moreover, an image (50 μm×50 μm) obtained by taking a picture of the obtained laminate with an atomic force microscope is shown in FIG. 16.

### Example 22

Except that polybutylene glycol diacrylate (trade name “PBOM2000”, made by Mitsubishi Rayon Co., Ltd.) was laminated in a thickness of 2 μm as the active energy ray curable composition for forming an undercoat layer, the same operation as Example 2 was performed to obtain a laminate.

The surface shape and so on of the obtained laminate are shown in Table 2. Moreover, an image (50 μm×50 μm) obtained by taking a picture of the obtained laminate with an atomic force microscope is shown in FIG. 10. An image obtained by Fourier-transforming an image obtained by taking a picture with an atomic force microscope is shown in FIG. 11.

### Comparative Example 9

A mirror stainless steel plate of 20 cm×20 cm was processed with alumina particles (trade name: “A400S”) under the conditions of a pressure of 0.3 MPa, a speed of 20 mm/s, a pitch of 2.5 mm, and a supply amount of 30% with a blast apparatus (machine model: “PAM107”, made by Nicchu Co., Ltd.) to obtain a mold.

On the obtained mold, polyethylene glycol diacrylate (trade name: “A-200”, made by Shin Nakamura Chemical Co., Ltd.) was added dropwise as an active energy ray curable composition for forming an undercoat layer, a glass substrate (trade name: “Eagle XG”, made by Corning Inc.; 5 cm long, 5 cm wide, and 0.7 mm thick) having been subjected to an excimer cleaning (172 nm UV lamp, made by M.D. Excimer Inc.) was covered thereon, and then the active energy ray curable composition was spread with a hand roll. The active energy ray curable composition was UV-irradiated (integrated dose: 1000 mJ/cm²) through a glass to be cured, and was then peeled from the mold. Then, an undercoat layer was laminated on the substrate.

Then, on the undercoat layer, ITO of 100 nm was laminated with an RF sputtering apparatus (machine model “SVC-700RF”, made by Sanyu Electronic Inc.) to obtain a laminate.

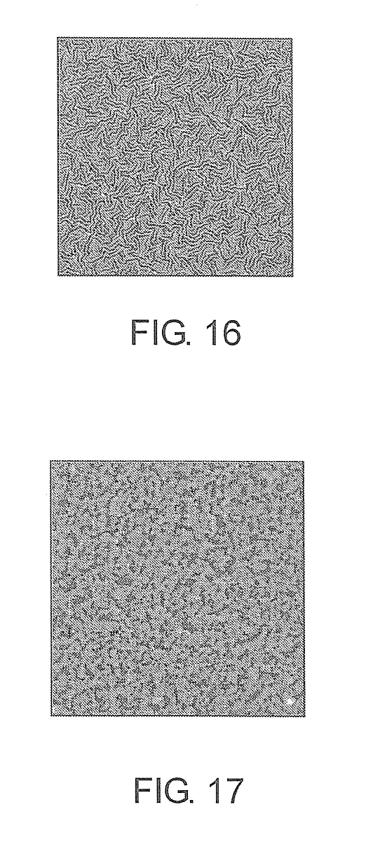

The surface shape and so on of the obtained laminate are shown in Table 2. Moreover, an image (50 μm×50 μm) obtained by taking a picture of the obtained laminate with an atomic force microscope is shown in FIG. 17.

TABLE 1

| | | Undercoat layer | | | | | | | |
|---|---|---|---|---|---|---|---|---|---|
| | | | Elastic | Inorganic film | | Surface roughness | | | |
| | Substrate | | modulus | | Thickness | Ra | Ry | Rz | RMS |
| | Material | Material | (MPa) | Material | (nm) | (nm) | (nm) | (nm) | (nm) |
| Example 1 | Glass | Resin A | 153 | ITO | 20 | 28.5 | 228.3 | 200.2 | 34.1 |
| Example 2 | Glass | Resin A | 153 | ITO | 40 | 32.5 | 310.7 | 251.3 | 39.6 |
| Example 3 | Glass | Resin A | 153 | ITO | 60 | 50.6 | 417.9 | 372.3 | 62.3 |
| Example 4 | Glass | Resin A | 153 | ITO | 80 | 86.4 | 653.1 | 528.6 | 103.4 |
| Example 5 | Glass | Resin A | 153 | ITO | 100 | 148.5 | 1110.5 | 997.9 | 182.6 |
| Example 6 | Glass | Resin A | 153 | ITO | 300 | 406.4 | 2836.0 | 1538.2 | 490.7 |
| Comparative Example 1 | Glass | — | — | ITO | 100 | — | — | — | — |
| Example 7 | Resin | Resin A | 153 | ITO | 100 | 60.3 | 517.6 | 439.5 | 76.1 |
| Example 8 | Glass | Resin A | 153 | IZO | 50 | 43.0 | 411.5 | 314.0 | 53.1 |
| Example 9 | Glass | Resin A | 153 | IZO | 100 | 61.5 | 469.1 | 390.9 | 74.3 |
| Example 10 | Glass | Resin B | 149 | IZO | 50 | 44.7 | 402.9 | 353.8 | 55.0 |
| Example 11 | Glass | Resin B | 149 | IZO | 100 | 63.3 | 467.7 | 422.7 | 76.7 |
| Comparative Example 2 | Glass | — | — | IZO | 100 | — | — | — | — |
| Example 12 | Glass | Resin A | 153 | ZrO₂ | 5 | 17.6 | 168.5 | 139.7 | 21.5 |
| Example 13 | Glass | Resin A | 153 | ZrO₂ | 36 | 36.8 | 316.4 | 264.5 | 44.9 |
| Comparative Example 3 | Glass | — | — | ZrO₂ | 5 | — | — | — | — |
| Example 14 | Glass | Resin A | 153 | SiO₂ | 10 | 41.6 | 327.8 | 226.1 | 51.0 |
| Comparative Example 4 | Glass | — | — | SiO₂ | 10 | — | — | — | — |

| | | | Number of | | Average | Average | |
|---|---|---|---|---|---|---|---|
| | Line | | approximate | Interval of | pitch of | height of | |
| | roughness | | curves with | reciprocal of | uneven | uneven | Value of |
| | Sm | Resistance | maximum | frequency | structure | structure | formula |
| | (μm) | (Ω) | values observed | (μm) | (μm) | (μm) | (1) |
| Example 1 | 1.6 | 134 | >30 | 0.98 | 1.04 | 0.12 | 0.30 |
| Example 2 | 1.9 | 100 | >30 | 0.94 | 1.02 | 0.10 | 0.40 |
| Example 3 | 2.5 | 88 | >30 | 1.00 | 1.01 | 0.22 | 0.25 |
| Example 4 | 5.0 | 85 | >30 | 1.00 | 1.06 | 0.35 | 0.28 |
| Example 5 | 5.2 | 76 | >30 | 1.01 | 1.12 | 0.44 | 0.33 |
| Example 6 | 22.6 | 54 | >30 | 0.98 | 1.70 | 0.95 | 0.76 |
| Comparative Example 1 | — | 78 | — | — | — | — | — |
| Example 7 | 3.4 | 165 | >30 | 1.03 | 1.32 | 0.14 | 0.36 |
| Example 8 | 2.2 | 56 | >30 | 0.75 | 1.01 | 0.21 | 0.27 |
| Example 9 | 3.5 | 18 | >30 | 0.68 | 1.08 | 0.10 | 0.58 |
| Example 10 | 2.3 | 33 | >30 | 0.67 | 1.03 | 0.18 | 0.37 |
| Example 11 | 3.6 | 15 | >30 | 0.83 | 1.05 | 0.19 | 0.68 |
| Comparative Example 2 | — | 18 | — | — | — | — | — |
| Example 12 | 1.2 | >1500 | >30 | 2.34 | 1.38 | 0.70 | 0.34 |
| Example 13 | 1.5 | >1500 | >30 | 4.93 | 2.07 | 0.12 | 0.47 |
| Comparative Example 3 | — | >1500 | — | — | — | — | — |
| Example 14 | 1.1 | >1500 | >30 | 5.49 | 3.02 | 0.13 | 0.43 |
| Comparative Example 4 | — | >1500 | — | — | — | — | — |

TABLE 2

| | | Undercoat layer | | First layer of | | Second layer of | | | | | |
|---|---|---|---|---|---|---|---|---|---|---|---|
| | | | Elastic | inorganic film | | inorganic film | | Surface Roughness | | | |
| | Substrate | | modulus | | Thickness | | Thickness | Ra | Ry | Rz | RMS |
| | Material | Material | (MPa) | Material | (nm) | Material | (nm) | (nm) | (nm) | (nm) | (nm) |
| Example 15 | Glass | Resin A | 153 | ZrO₂ | 5 | ITO | 100 | 72.4 | 690.9 | 553.0 | 99.7 |
| Example 16 | Glass | Resin A | 153 | ZrO₂ | 5 | ITO | 200 | 89.5 | 787.8 | 514.5 | 110.2 |
| Comparative Example 5 | Glass | — | — | ZrO₂ | 5 | ITO | 100 | — | — | — | — |
| Comparative Example 6 | Glass | — | — | ZrO₂ | 5 | ITO | 200 | — | — | — | — |
| Example 17 | Glass | Resin A | 153 | SiO₂ | 10 | ITO | 100 | 54.6 | 460.0 | 223.8 | 67.1 |
| Example 18 | Glass | Resin A | 153 | SiO₂ | 10 | IZO | 100 | 85.5 | 622.3 | 417.8 | 102.8 |
| Comparative Example 7 | Glass | — | — | SiO₂ | 10 | ITO | 100 | — | — | — | — |
| Comparative Example 8 | Glass | — | — | SiO₂ | 10 | IZO | 100 | — | — | — | — |
| Example 19 | Glass | Resin C | 1505 | ITO | 40 | — | — | 5.9 | 66.0 | 57.0 | 7.4 |
| Example 20 | Glass | Resin D | 95 | ITO | 40 | — | — | 10.1 | 106.4 | 93.4 | 12.5 |
| Example 21 | Glass | Resin E | 42 | ITO | 40 | — | — | 19.5 | 217.1 | 171.7 | 23.8 |
| Example 22 | Glass | Resin F | 22 | ITO | 40 | — | — | 78.8 | 547.3 | 484.2 | 92.7 |
| Comparative Example 9 | Glass | Resin G | 1505 | ITO | 100 | — | — | 53.5 | 686.9 | 590.9 | 67.1 |

| | | | Number of | | Average | Average | |
|---|---|---|---|---|---|---|---|
| | Line | | approximate | Interval of | pitch of | height of | |
| | roughness | | curves with | reciprocal of | uneven | uneven | Value of |
| | Sm | Resistance | maximum | frequency | structure | structure | formula |
| | (μm) | (Ω) | values observed | (μm) | (μm) | (μm) | (1) |
| Example 15 | 2.3 | 996 | >30 | 0.77 | 1.08 | 0.23 | 0.32 |
| Example 16 | 2.9 | 426 | >30 | 1.11 | 1.57 | 0.33 | 0.38 |
| Comparative Example 5 | — | 1018 | — | — | — | — | — |
| Comparative Example 6 | — | 445 | — | — | — | — | — |
| Example 17 | 0.7 | 69 | >30 | 1.38 | 1.91 | 0.32 | 0.61 |
| Example 18 | 0.5 | 17 | >30 | 1.69 | 1.98 | 0.40 | 0.40 |
| Comparative Example 7 | — | 79 | — | — | — | — | — |
| Comparative Example 8 | — | 23 | — | — | — | — | — |
| Example 19 | 0.9 | 38 | >30 | 0.17 | 0.30 | 0.01 | 0.37 |
| Example 20 | 1.0 | 43 | >30 | 0.33 | 0.60 | 0.02 | 0.21 |
| Example 21 | 1.2 | 54 | >30 | 0.62 | 0.87 | 0.05 | 0.23 |
| Example 22 | 3.6 | 78 | >30 | 0.71 | 2.87 | 0.27 | 0.33 |
| Comparative Example 9 | 2.1 | 131 | <10 | — | — | — | 0.40 |

The abbreviations in Tables 1 and 2 represent the following compounds, etc.

Resin A: a resin formed by performing UV-curing on “Diabeam UM-8002”.

Resin B: a resin formed by performing UV-curing on “Diabeam UM-8003-1”.

Resin C: a resin formed by performing UV-curing on “A-200”.

Resin D: a resin formed by performing UV-curing on “A-400”.

Resin E: a resin formed by performing UV-curing on “A-1000”.

Resin F: a resin formed by performing UV-curing on “PBOM2000”.

ITO: indium tin oxide

IZO: indium zinc oxide

ZrO₂: zirconium oxide

SiO₂: silicon dioxide

### Comparative Example 10

A glass substrate (trade name “Eagle XG”, made by Corning Inc.) of 25 mm×25 mm was disposed in the chamber of a sputtering apparatus, and ITO of 100 nm thick was evaporated through a mask having a line pattern under the conditions of a chamber pressure of 0.1 Pa and an evaporation speed of 0.1 nm/s to obtain a laminate having a first electrode on the glass substrate. The linewidth of the formed ITO film was 2 nm.

After a UV-ozone treatment was performed on the obtained laminate, the laminate was disposed in the chamber of the vacuum evaporation apparatus, and the followings were evaporated on the ITO in order under the conditions of a chamber pressure of 10⁻⁴ Pa and an evaporation speed of 1.0 nm/s: N,N′-di(1-naphthyl)-N,N′-diphenylbenzidine of 50 nm thick as a hole transport layer, tris(2-phenylpyridine)iridium doped 4,4′-N,N′-dicarbazole-diphenyl of 20 nm thick as a light-emitting layer, and 2,2′,2″-(1,3,5-benzenetolyl)-tris(1-phenyl-1-1H-benzimidazole) of 50 nm thick as an electron transport. Then, on the electron transport layer, lithium fluoride was evaporated in a thickness of 0.7 nm as an electron injection layer under the condition of an evaporation speed of 0.059 nrn/s. Under the condition of an evaporation speed of 0.5 nm/s, aluminum of 1.5 nm thick and silver of 100 nm thick were evaporated in order, through a mask having a line pattern, as a second electrode. At this point, the line pattern was disposed substantially orthogonal to the ITO. The linewidth of the second electrode of the formed film was 2 nm. An EL element was obtained with the above steps. The light-emitting portion of the EL element was the overlapping portion of the first electrode and the second electrode. That is, the size of the light-emitting portion was 2 mm×2 mm.

The obtained EL element was added to an etched glass and sealed with an epoxy-based sealant (by Nagase ChemteX Corporation) to obtain a surface light emitter. The light extraction efficiency of the obtained surface light emitter is shown in Table 3.

### Example 23

Except that the laminate obtained in Example 5 was used as the laminate in which the glass substrate has a first electrode thereon, the same operation as Comparative Example 10 was performed to obtain a surface light emitter. The light extraction efficiency of the obtained surface light emitter is shown in Table 3.

### Comparative Example 11

Except that the laminate obtained in Comparative Example 9 was used as the laminate in which the glass substrate has a first electrode thereon, the same operation as Comparative Example 10 was performed to obtain a surface light emitter. The light extraction efficiency of the obtained surface light emitter is shown in Table 3.

TABLE 3

| | Light extraction efficiency(%) |
|---|---|
| Comparative Example 10 | 100 |
| Example 23 | 149 |
| Comparative Example 11 | 102 |

In each of Examples 1 to 22, a laminate having an uneven structure of an inorganic film at the surface, for which a maximum value was observed in 18 or more of the first sixth-order polynomial approximate curves, was obtained. Moreover, in each of Comparative Examples 1 to 8, since an undercoat layer was not included, a laminate without an uneven structure at the surface was obtained. Moreover, in Comparative Example 9, a laminate having an uneven structure of an inorganic film on the surface, for which a maximum value was observed in 17 or less of the first sixth-order polynomial approximate curves, was obtained.

Since the surface light emitter obtained in Example 23 contains the laminate obtained in Example 5, the light extraction efficiency is superior. Moreover, since the surface light emitter obtained in Comparative Example 10 was built by a laminate without an uneven structure at the surface, the light extraction efficiency is poor. Moreover, since the surface light emitter obtained in Comparative Example 11 was built by the laminate for which a maximum value was observed in 17 or less of the first sixth-order polynomial approximate curves obtained in Comparative Example 9, the light extraction efficiency is poor.

### INDUSTRIAL APPLICATION

Since the laminate of the aspects of the invention has a conductive inorganic film at the surface and has a corrugated uneven structure at the surface, the laminate can be expected to be used in a broad range of applications, and is suitable for a surface light emitter having superior light extraction efficiency and capable of uniform irradiation in a broad range or a solar cell having superior light confining efficiency.

### Description of Reference Characters

10, 210, 211, 310, 311: laminate

11: substrate

12: undercoat layer

13: inorganic layer

20: surface light emitter

21: light emitting layer

22: second electrode

23: first electrode

30: solar cell

31: photoelectric conversion layer

32: back electrode

33: transparent electrode

1. A laminate, comprising:
a substrate;
an undercoat layer on the substrate; and
an inorganic film on the undercoat layer, wherein
the inorganic film includes at least one material of a conductive metal oxide and a conductive metal nitride, and
in an image obtained by Fourier transforming an image obtained by using an atomic force microscope to take a picture of a surface of the inorganic film, an azimuth angle of the image obtained from the Fourier transformation from a center of the image toward a direction of 12 o'clock is set to 0°, and in first approximate curves of 36 brightness value plots obtained by radially plotting the brightness values every 10° from 0°, a maximum value is observed in 18 or more of the first approximate curves.

2. The laminate of claim 1, wherein in a second approximate curve of a plot obtained by summing the 36 brightness value plots and calculating and plotting moving averages of a resulting plot of the summation,
a frequency at which a brightness value is a minimum value between a frequency of 0.2 μm-1 and a frequency at which a brightness value is a maximum value is set as frequency A, and a largest frequency among frequencies at which the brightness value is half of the maximum value is set as frequency B, and
a difference between a reciprocal of frequency A and a reciprocal of frequency B ranges from 0.01 μm to 10 μm.

3. The laminate of claim 1, wherein an average pitch of an uneven structure of the surface of the inorganic film ranges from 0.05 μm to 4 μm.

4. The laminate of claim 1, wherein an average height of protruding portions of an uneven structure of the surface of the inorganic film ranges from 0.01 μm to 2 μm.

5. The laminate of claim 1, wherein a surface roughness Ra, a line roughness Ra′, a maximum value of line roughness Ra′(max), and a minimum value of line roughness Ra′(min) of the surface of the inorganic film satisfy formula (1):
13≦(Ra′(max)−Ra′(min))/Ra≦0.82 (1).

6. The laminate of claim 1, wherein an elastic modulus of the undercoat layer is 1800 MPa or less.

7. The laminate of claim 1, wherein the inorganic film comprises at least one material selected from the group consisting of indium tin oxide, indium zinc oxide, indium oxide, zinc oxide, tin oxide, zirconium oxide, indium nitride, gallium nitride, aluminum nitride, zirconium nitride, and titanium nitride.

8. A method for producing a laminate, comprising:
coating, on a substrate, an active energy ray curable composition that contains a monomer having at least one of a urethane group, a phenyl group, and an alkylene oxide group,
irradiating with an active energy ray such that the active energy ray curable composition is cured to form an undercoat layer,
forming an uneven structure on a surface of the undercoat layer, comprising: laminating an inorganic film comprising at least one material of a conductive metal oxide and a conductive metal nitride with any one of a sputtering method, an evaporation method, and a chemical vapor deposition method.

9. The method of claim 8, wherein the inorganic film comprises at least one material selected from the group consisting of indium tin oxide, indium zinc oxide, indium oxide, zinc oxide, tin oxide, zirconium oxide, indium nitride, gallium nitride, aluminum nitride, zirconium nitride, and titanium nitride.

10. The method of claim 8, wherein a method for the lamination on the undercoat layer is a sputtering method or an evaporation method.

11. An electrode, comprising the laminate of claim 1.

12. An electroluminescent element, comprising the laminate of claim 1.

13. A surface light emitter, comprising the electroluminescent element of claim 12.

14. A solar cell, comprising the laminate of claim 1.
